(19) United States
(12) Patent Application Publication
(10) Pub. No.: US 2025/0063925 A1
(43) Pub. Date: Feb. 20, 2025

(54) DISPLAY DEVICE

(71) Applicant: Samsung Display Co., LTD., Yongin-si (KR)

(72) Inventors: YONGSUB SHIM, Yongin-si (KR); JEWON YOO, Yongin-si (KR); JUNGMIN CHOI, Yongin-si (KR); JONGBEOM HONG, Yongin-si (KR)

(21) Appl. No.: 18/743,851

(22) Filed: Jun. 14, 2024

(30) Foreign Application Priority Data
Aug. 17, 2023 (KR) 10-2023-0107721

(51) Int. Cl. H10K 59/80; H10K 59/19

(52) U.S. Cl. CPC H10K 59/8792; H10K 59/19

(57) ABSTRACT

A display device includes: a substrate including a display area including a first display area, and a second display area spaced from the first display area in a first direction; a plurality of pixels located along the first direction and a second direction crossing the first direction on the substrate in the display area; a plurality of first light blocking patterns located along the second direction on the substrate in the first display area, each of the plurality of first light blocking patterns extending in the first direction; and a plurality of second light blocking patterns located along the first direction on the substrate in the second display area, each of the plurality of second light blocking patterns extending in the second direction. The plurality of second light blocking patterns and the plurality of first light blocking patterns have the same height as each other.

### CROSS-REFERENCE TO RELATED APPLICATION

The present application claims priority to and the benefit of Korean Patent Application No. 10-2023-0107721, filed on Aug. 17, 2023, in the Korean Intellectual Property Office, the entire disclosure of which is incorporated by reference herein.

### BACKGROUND

### 1. Field

Aspects of embodiments of the present disclosure relate to a display device that provides visual information.

### 2. Description of the Related Art

With the development of information technology, the importance of a display device, which is a connection medium between a user and information, has been highlighted. For example, the use of display devices, such as a liquid crystal display (LCD) device, an organic light emitting display (OLED) device, a plasma display panel (PDP) device, a quantum dot display device, or the like, is increasing.

In general, a display device is manufactured to provide a wide viewing angle, but it may be desirable to limit the viewing angle for various reasons, such as privacy and information protection. For example, it may be desirable for devices such as ATMs of financial institutions, laptops, tablet PCs, and the like to have a viewing angle that is limited in a left-right direction or an up-down direction to protect the user's privacy.

When the display device is applied to an automotive display device, and the display device has a wide viewing angle, an image displayed on the display device may reduce the driver's concentration. Further, the image displayed on the display device may be reflected from a front windshield of the automobile, and may interfere with the driver's operation. Accordingly, it may be desirable to limit the viewing angle of the display device in a left-right direction or an up-down direction.

The above information disclosed in this Background section is for enhancement of understanding of the background of the present disclosure, and therefore, it may contain information that does not constitute prior art.

### SUMMARY

One or more embodiments of the present disclosure may be directed to a display device having an adjustable viewing angle and/or improved process efficiency.

According to one or more embodiments of the present disclosure, a display device includes: a substrate including a display area including a first display area, and a second display area spaced from the first display area in a first direction; a plurality of pixels located along the first direction and a second direction crossing the first direction on the substrate in the display area; a plurality of first light blocking patterns located along the second direction on the substrate in the first display area, each of the plurality of first light blocking patterns extending in the first direction; and a plurality of second light blocking patterns located along the first direction on the substrate in the second display area, each of the plurality of second light blocking patterns extending in the second direction. The plurality of second light blocking patterns and the plurality of first light blocking patterns have the same height as each other.

In an embodiment, the plurality of first light blocking patterns and the plurality of second light blocking patterns may be located in the same layer as each other.

In an embodiment, each of the plurality of pixels may include: a first pixel including a first light emitting element; and a second pixel including a second light emitting element configured to emit light of the same color as that of the first light emitting element. A first pixel electrode of the first light emitting element may be spaced from a second pixel electrode of the second light emitting element.

In an embodiment, in the first display area, some of the plurality of first light blocking patterns may partially overlap with the first light emitting element and the second light emitting element in a plan view.

In an embodiment, in the second display area, the plurality of second light blocking patterns may be spaced from the first light emitting element and the second light emitting element in a plan view.

In an embodiment, when the display device is driven in a first mode, each of the first light emitting element and the second light emitting element may be configured to emit light in the second display area; and when the display device is driven in a second mode different from the first mode, the first light emitting element may be configured to emit light and the second light emitting element may be configured to not emit light in the second display area.

In an embodiment, when the display device is driven in a first mode, the first light emitting element may be configured to not emit light and the second light emitting element may be configured to emit light in the second display area; and when the display device is driven in a second mode different from the first mode, the first light emitting element may be configured to emit light and the second light emitting element may be configured to not emit light in the second display area.

In an embodiment, each of the plurality of first light blocking patterns and the plurality of second light blocking patterns may include an organic material including a light blocking material having a black color.

In an embodiment, the display area may further include a third display area between the first display area and the second display area, some of the plurality of pixels being located in the third display area, and the plurality of first light blocking patterns and the plurality of second light blocking patterns may be spaced from the third display area in a plan view.

According to one or more embodiments of the present disclosure, a display device includes: a substrate including a display area including a first display area, and a second display area spaced from the first display area in a first direction; a plurality of pixels located along the first direction and a second direction crossing the first direction on the substrate in the display area; a plurality of first light blocking patterns located along the second direction on the substrate in the first display area, each of the plurality of first light blocking patterns extending in the first direction; a plurality of second light blocking patterns located along the first direction on the substrate in the second display area, each of the plurality of second light blocking patterns extending in the second direction; and a plurality of third light blocking patterns located along the first direction on the substrate in the first display area, each of the plurality of third light blocking patterns extending in the second direction. The plurality of first light blocking patterns, the plurality of second light blocking patterns, and the plurality of third light blocking patterns have the same height as each other.

In an embodiment, the plurality of first light blocking patterns, the plurality of second light blocking patterns, and the plurality of third light blocking patterns may be located in the same layer as each other.

In an embodiment, each of the plurality of pixels may include: a first pixel including a first light emitting element; and a second pixel including a second light emitting element configured to emit light of the same color as that of the first light emitting element. A first pixel electrode of the first light emitting element may be spaced from a second pixel electrode of the second light emitting element.

In an embodiment, in the first display area, some of the plurality of first light blocking patterns may partially overlap with the first light emitting element and the second light emitting element in a plan view.

In an embodiment, the plurality of second light blocking patterns may be spaced from the first light emitting element and the second light emitting element in a plan view in the second display area, and the plurality of third light blocking patterns may be spaced from the first light emitting element and the second light emitting element in a plan view in the first display area.

In an embodiment, when the display device is driven in a first mode, each of the first light emitting element and the second light emitting element may be configured to emit light in the first display area and the second display area; when the display device is driven in a second mode different from the first mode, the first light emitting element may be configured to not emit light and the second light emitting element may be configured to emit light in the first display area; and when the display device is driven in the second mode, the first light emitting element may be configured to emit light and the second light emitting element may be configured to not emit light in the second display area.

In an embodiment, when the display device is driven in a first mode, the first light emitting element may be configured to emit light and the second light emitting element may be configured to not emit light in the first display area; when the display device is driven in the first mode, the first light emitting element may be configured to not emit light and the second light emitting element may be configured to emit light in the second display area; when the display device is driven in a second mode different from the first mode, the first light emitting element may be configured to not emit light and the second light emitting element may be configured to emit light in the first display area; and when the display device is driven in the second mode, the first light emitting element may be configured to emit light and the second light emitting element may be configured to not emit light in the second display area.

In an embodiment, each of the plurality of first light blocking patterns, the plurality of second light blocking patterns, and the plurality of third light blocking patterns may include an organic material including a light blocking material having a black color.

In an embodiment, the display area may further include a third display area between the first display area and the second display area, some of the plurality of pixels being located in the third display area, and the plurality of first light blocking patterns, the plurality of second light blocking patterns, and the plurality of third light blocking patterns may be spaced from the third display area in a plan view.

According to one or more embodiments of the present disclosure, a display device includes: a substrate including a display area including a first display area, and a second display area spaced from the first display area in a first direction; a plurality of pixels located along the first direction and a second direction crossing the first direction on the substrate in the display area; a plurality of first light blocking patterns located along the second direction on the substrate in the first display area, each of the plurality of first light blocking patterns extending in the first direction; a plurality of second light blocking patterns located along the first direction on the substrate in the second display area, each of the plurality of second light blocking patterns extending in the second direction; a plurality of third light blocking patterns located along the first direction on the substrate in the first display area, each of the plurality of third light blocking patterns extending in the second direction; and a plurality of fourth light blocking patterns located along the second direction on the substrate in the second display area, each of the plurality of fourth light blocking patterns extending in the first direction. The plurality of first light blocking patterns, the plurality of second light blocking patterns, the plurality of third light blocking patterns, and the plurality of fourth light blocking patterns have the same height as each other.

In an embodiment, the plurality of first light blocking patterns, the plurality of second light blocking patterns, the plurality of third light blocking patterns, and the plurality of fourth light blocking patterns may be located in the same layer as each other.

In an embodiment, each of the plurality of pixels may include: a first pixel including a first light emitting element; and a second pixel including a second light emitting element configured to emit light of the same color as that of the first light emitting element. A first pixel electrode of the first light emitting element may be spaced from a second pixel electrode of the second light emitting element.

In an embodiment, some of the plurality of first light blocking patterns may partially overlap with the first light emitting element and the second light emitting element in the first display area in a plan view, and some of the plurality of fourth light blocking patterns may partially overlap with the first light emitting element and the second light emitting element in the second display area in a plan view.

In an embodiment, the plurality of second light blocking patterns may be spaced from the first light emitting element and the second light emitting element in the second display area in a plan view, and the plurality of third light blocking patterns may be spaced from the first light emitting element and the second light emitting element in the first display area in a plan view.

In an embodiment, when the display device is driven in a first mode, each of the first light emitting element and the second light emitting element may be configured to emit light in the first display area and the second display area; when the display device is driven in a second mode different from the first mode, the first light emitting element may be configured to not emit light and the second light emitting element may be configured to emit light in the first display area; and when the display device is driven in the second mode, the first light emitting element may be configured to emit light and the second light emitting element may be configured to not emit light in the second display area.

In an embodiment, when the display device is driven in a first mode, the first light emitting element may be configured to emit light and the second light emitting element may be configured to not emit light in the first display area; when the display device is driven in the first mode, the first light emitting element may be configured to not emit light and the second light emitting element may be configured to emit light in the second display area; when the display device is driven in a second mode different from the first mode, the first light emitting element may be configured to not emit light and the second light emitting element may be configured to emit light in the first display area; and when the display device is driven in the second mode, the first light emitting element may be configured to emit light and the second light emitting element may be configured to not emit light in the second display area.

In an embodiment, each of the plurality of first light blocking patterns, the plurality of second light blocking patterns, the plurality of third light blocking patterns, and the plurality of fourth light blocking patterns may include an organic material including a light blocking material having a black color.

In an embodiment, the display area may further include a third display area between the first display area and the second display area, some of the plurality of pixels being located in the third display area.

In an embodiment, the plurality of first light blocking patterns, the plurality of second light blocking patterns, the plurality of third light blocking patterns, and the plurality of fourth light blocking patterns may be spaced from the third display area in a plan view.

In an embodiment, the display device may further include: a plurality of fifth light blocking patterns located along the second direction on the substrate in the third display area, each of the plurality of fifth light blocking patterns extending in the first direction; and a plurality of sixth light blocking patterns located along the first direction on the substrate in the third display area, each of the plurality of sixth light blocking patterns extending in the second direction. The plurality of first light blocking patterns, the plurality of second light blocking patterns, the plurality of third light blocking patterns, the plurality of fourth light blocking patterns, the plurality of fifth light blocking patterns, and the plurality of sixth light blocking patterns may have the same height as each other.

In an embodiment, the plurality of first light blocking patterns, the plurality of second light blocking patterns, the plurality of third light blocking patterns, the plurality of fourth light blocking patterns, the plurality of fifth light blocking patterns, and the plurality of sixth light blocking patterns may be located in the same layer as each other.

In an embodiment, the plurality of fifth light blocking patterns may be connected to the plurality of first light blocking patterns and the plurality of fourth light blocking patterns.

According to one or more embodiments of the present disclosure, a display device may include a substrate including a first display area and a second display area spaced apart from the first display area in a first direction. First light blocking patterns may be disposed along a second direction crossing the first direction on the substrate in the first display area, and second light blocking patterns may be disposed along the first direction on the substrate in the second display area. Each of the first light blocking patterns may extend in the first direction, and each of the second light blocking patterns may extend in the second direction. The first light blocking patterns and the second light blocking patterns may have the same or substantially the same height as each other.

In some embodiments, the first light blocking patterns and the second light blocking patterns may include the same material as each other, and may be formed through the same process as each other. In other words, by concurrently or substantially simultaneously forming the first light blocking patterns and the second light blocking patterns together through one process, a process efficiency for manufacturing the display device may be improved.

In some embodiments, the second light blocking patterns may be spaced apart from a light emitting element in a plan view. Accordingly, when compared to a case in which the second light blocking patterns overlap with the light emitting element in a plan view, the luminance of the display device may be relatively increased.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIG. 1 is a plan view illustrating a display device according to an embodiment of the present disclosure.

FIG. 2 is an enlarged plan view of the area ‘A’ of FIG. 1.

FIG. 3 is a cross-sectional view taken the along line I-I′ of FIG. 2.

FIG. 4 is an enlarged plan view of the area ‘B’ of FIG. 1.

FIG. 5 is a cross-sectional view taken along the line II-II′ of FIG. 4 according to an embodiment of the present disclosure.

FIG. 6 is a cross-sectional taken along the line II-II′ of FIG. 4 according to another embodiment of the present disclosure.

FIG. 7 is an enlarged plan view of the area ‘C’ of FIG. 1.

FIG. 8 is a cross-sectional view taken along the line III-III′ of FIG. 7.

FIGS. 9-11 are cross-sectional views taken along the line II-II′ of FIG. 4.

FIG. 12 is a cross-sectional view of a display device according to a comparative example.

FIG. 13 is a cross-sectional view taken along the line II-II′ of FIG. 4.

FIG. 14 illustrates a relationship between a viewing angle and a luminance in the display device of FIG. 12.

FIGS. 15 and 16 illustrate relationships between a viewing angle and a luminance in the display device of FIG. 13.

FIG. 17 is a cross-sectional view taken along the line I-I′ of FIG. 2.

FIG. 18 is a plan view illustrating a display device according to another embodiment of the present disclosure.

FIG. 19 is an enlarged plan view of the area ‘D’ of FIG. 18.

FIGS. 20-23 are cross-sectional views taken along the line IV-IV′ of FIG. 19.

FIG. 24 is a plan view illustrating a display device according to another embodiment of the present disclosure.

FIG. 25 is an enlarged plan view of the area ‘E’ of FIG. 24.

FIGS. 26 and 27 are cross-sectional views taken along the line V-V′ of FIG. 25.

FIG. 28 is a plan view illustrating a display device according to another embodiment of the present disclosure.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and 1 “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

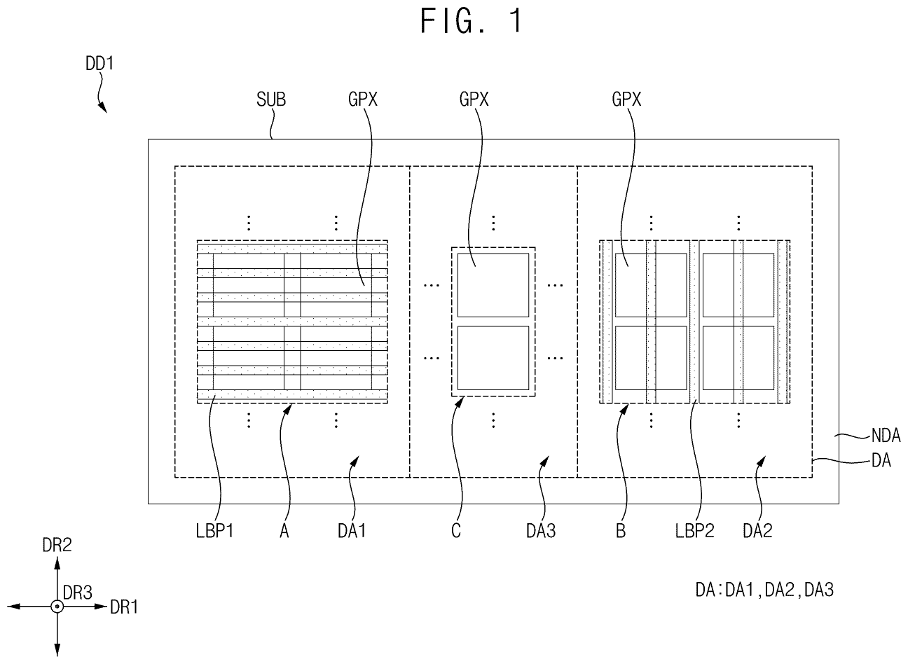

FIG. 1 is a plan view illustrating a display device according to an embodiment of the present disclosure.

As used herein, a plane may be defined by a first direction DR1, and a second direction DR2 crossing the first direction DR1. For example, the first direction DR1 and the second direction DR2 may be perpendicular or substantially perpendicular to each other. The first direction DR1 may refer to a left-right direction (e.g., a horizontal direction) in a plan view. In other words, one side of the first direction DR1 may refer to a left direction in a plan view, and the other side of the first direction DR1 may refer to a right direction in a plan view. The second direction DR2 may refer to an up-down direction (e.g., a vertical direction) in a plan view. In other words, one side of the second direction DR2 may refer to an upward direction in a plan view, and the other side of the second direction DR2 may refer to a downward direction in a plan view. A direction normal to the plane, or in other words, a thickness direction of a display device DD1, may be a third direction DR3. In other words, the third direction DR3 may be perpendicular or substantially perpendicular to each of the first direction DR1 and the second direction DR2. The third direction DR3 may refer to a front direction of the display device DD1.

Referring to FIG. 1, the display device DD1 according to an embodiment of the present disclosure may include a substrate SUB, group pixels GPX, first light blocking patterns LBP1, and second light blocking patterns LBP2.

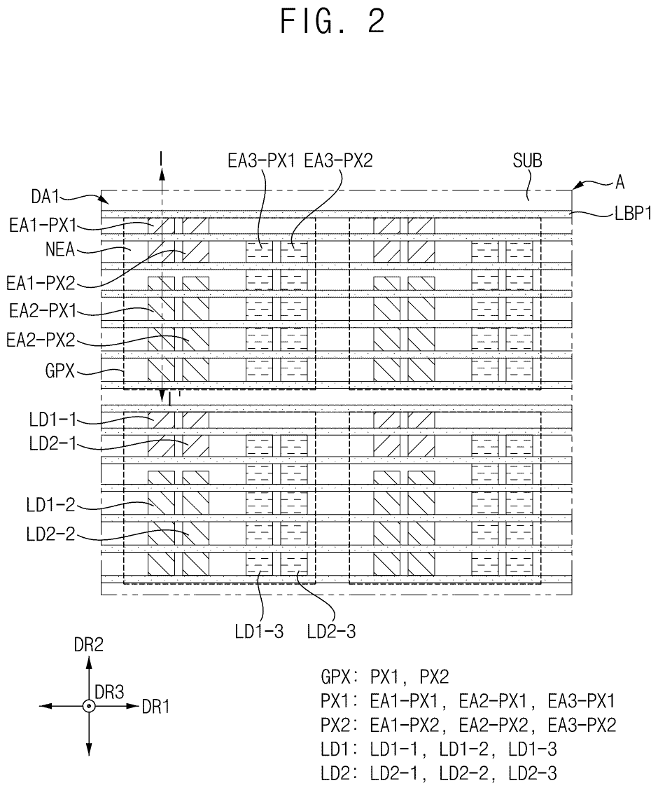

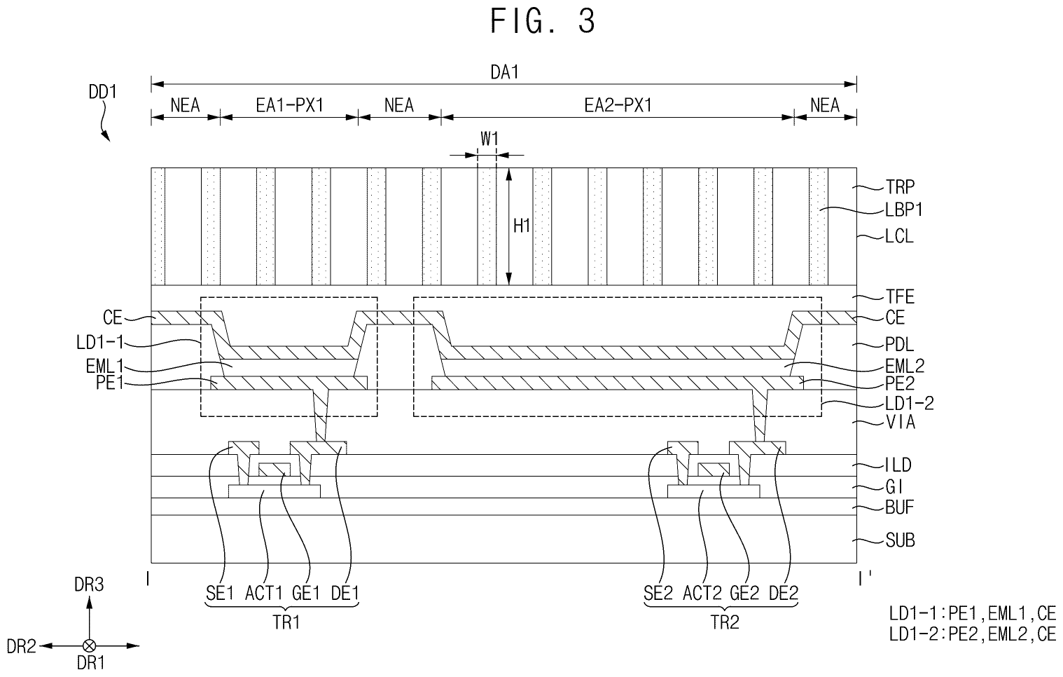

The substrate SUB may include a display area DA and a non-display area NDA. The display area DA may be defined as an area that displays an image by generating light, or by adjusting a transmittance of light provided from an external light source. A plurality of the group pixels GPX may be disposed in the display area DA. The group pixels GPX may generate light according to a driving signal. The group pixels GPX may be repeatedly disposed along the first direction DR1 and the second direction DR2 on the substrate SUB in the display area DA. Each of the group pixels GPX may include a first pixel (e.g., a first pixel PX1 of FIG. 2) and a second pixel (e.g., a second pixel PX2 of FIG. 2). A more detailed description thereof will be given below with reference to FIGS. 2 and 3.

The non-display area NDA may be defined as an area that does not display an image. For example, the non-display area NDA may entirely surround (e.g., around a periphery of) the display area DA. A driving chip and a plurality of pads for providing a driving signal to the group pixels GPX may be disposed in the non-display area NDA.

In an embodiment, the display area DA may have a rectangular planar shape. For example, a length of the display area DA in the first direction DR1 (e.g., the left-right direction) is greater than a length of the display area DA in the second direction DR2 (e.g., the up-down direction). As another example, the length of the display area DA in the second direction DR2 (e.g., the up-down direction) is greater than the length of the display area DA in the first direction DR1 (e.g., the left-right direction). However, the present disclosure is not limited thereto. For example, the display area DA may have one of a square planar shape, a circular planar shape, and/or an ellipse planar shape.

The display area DA may include a first display area DA1, a second display area DA2, and a third display area DA3.

The first display area DA1 may be spaced apart from the second display area DA2 in the first direction DR1, with the third display area DA3 interposed therebetween. For example, the first display area DA1 may be adjacent to a left side of the non-display area NDA in the first direction DR1. In other words, the first display area DA1 may be positioned on a left side of the display area DA. The first light blocking patterns LBP1 may be disposed in the first display area DA1. The first light blocking patterns LBP1 may be repeatedly disposed along the second direction DR2. The first light blocking patterns LBP1 may be spaced apart from each other in the second direction DR2. Each of the first light blocking patterns LBP1 may extend in the first direction DR1.

The second display area DA2 may be spaced apart from the first display area DA1 in the first direction DR1, with the third display area DA3 interposed therebetween. For example, the second display area DA2 may be adjacent to a right side of the non-display area NDA in the first direction DR1. In other words, the second display area DA2 may be positioned on a right side of the display area DA. The second light blocking patterns LBP2 may be disposed in the second display area DA2. The second light blocking patterns LBP2 may be repeatedly disposed along the first direction DR1. The second light blocking patterns LBP2 may be spaced apart from each other in the first direction DR1. Each of the second light blocking patterns LBP2 may extend in the second direction DR2.

The third display area DA3 may be disposed between the first display area DA1 and the second display area DA2 in a plan view. For example, the third display area DA3 may be positioned at (e.g., in or on) a center of the display area DA. In an embodiment, the first light blocking patterns LBP1 and the second light blocking patterns LBP2 may be spaced apart from the third display area DA3 in a plan view. In other words, the first light blocking patterns LBP1 and the second light blocking patterns LBP2 may not be disposed in the third display area DA3.

As illustrated in FIG. 1, the substrate SUB may include three display areas (e.g., the first to third display areas DA1, DA2, and DA3). However, the present disclosure is not limited thereto. For example, the substrate SUB may include two display areas. In this case, the substrate SUB may include the first display area DA1 on which the first light blocking patterns LBP1 are disposed, and the second display area DA2 on which the second light blocking patterns LBP2 are disposed. The first display area DA1 and the second display area DA2 may be adjacent to each other in the first direction DR1. As another example, the substrate SUB may include four or more display areas.

In an embodiment, each of the first blocking patterns LBP1 and the second light blocking patterns LBP2 may include an organic material including a light blocking material having a black color. For example, the light blocking material may include a black pigment, a black dye, carbon black, and/or the like. These may be used alone or in any suitable combination with each other.

A display device may be typically manufactured to provide a wide viewing angle, but depending on the application, it may be desirable for the viewing angle to be limited. For example, when the display device is applied to an automotive display device, if the display device has a wide viewing angle, an image displayed on the display device may reduce the driver's concentration. In addition, the image displayed on the display device may be reflected from a front windshield of the automobile, and may interfere with the driver's operation.

The display device DD1 according to an embodiment of the present disclosure may include the light blocking patterns LBP1 and LBP2 that block light incident at an angle greater than a certain angle (e.g., a predetermined angle), so that the viewing angle of the display device DD1 may be adjusted. In an embodiment, the display device DD1 may be applied to an automotive display device. In this case, a driver's seat may be positioned at (e.g., in or on) the front direction (e.g., the third direction DR3) of the first display area DA1, and a passenger seat may be positioned at (e.g., in or on) the right direction of the first display area DA1. In addition, the passenger seat may be positioned at (e.g., in or on) the front direction of the second display area DA2, and the driver's seat may be positioned at (e.g., in or on) the left direction of the second display area DA2. In addition, the driver's seat may be positioned at (e.g., in or on) the left direction of the third display area DA3, and the passenger seat may be positioned at (e.g., in or on) the right direction of the third display area DA3.

In another embodiment, the passenger seat may be positioned at (e.g., in or on) the front direction of the first display area DA1, and the driver's seat may be positioned at (e.g., in or on) the right direction of the first display area DA1. In addition, the driver's seat may be positioned at (e.g., in or on) the front direction of the second display area DA2, and the passenger seat may be positioned at (e.g., in or on) the left direction of the second display area DA2. In addition, the passenger seat may be positioned at (e.g., in or on) the left direction of the third display area DA3, and the driver's seat may be positioned at (e.g., in or on) the right direction of the third display area DA3. Hereinafter, a case where the driver's seat is positioned at (e.g., in or on) the front direction of the first display area DA1 and the passenger seat is positioned at (e.g., in or on) the front direction of the second display area DA2 may be described in more detail as a representative example.

However, the present disclosure is not limited to the above, and the display device DD1 may be applied to various suitable display devices that may desire adjustment of the viewing angle.

FIG. 2 is an enlarged plan view of the area ‘A’ of FIG. 1. FIG. 3 is a cross-sectional view taken along the line I-I′ of FIG. 2.

Referring to FIG. 2, the display device DD1 according to an embodiment of the present disclosure may include the substrate SUB, the group pixels GPX, and the first light blocking patterns LBP1 in the first display area DA1.

The group pixels GPX may be repeatedly disposed along the first direction DR1 and the second direction DR2 on the substrate SUB in the first display area DA1. Each of the group pixels GPX may include a first pixel PX1 and a second pixel PX2. For example, the first pixel PX1 may correspond to a left pixel of the group pixel GPX, and the second pixel PX2 may correspond to a right pixel of the group pixel GPX.

The first pixel PX1 may include a first light emitting area EA1-PX1, a second light emitting area EA2-PX1, and a third light emitting area EA3-PX1. Each of the first light emitting area EA1-PX1, the second light emitting area EA2-PX1, and the third light emitting area EA3-PX1 may be defined as an area that emits light.

The second pixel PX2 may include a first light emitting area EA1-PX2, a second light emitting area EA2-PX2, and a third light emitting area EA3-PX2. Each of the first light emitting area EA1-PX2, the second light emitting area EA2-PX2, and the third light emitting area EA3-PX2 may be defined as an area that emits light.

For example, each of the first light emitting areas EA1-PX1, EA1-PX2, the second light emitting areas EA2-PX1, EA2-PX2, and the third light emitting areas EA3-PX1, EA3-PX2 may have a rectangular planar shape. However, the present disclosure is not limited thereto. As another example, each of the first light emitting areas EA1-PX1, EA1-PX2, the second light emitting areas EA2-PX1, EA2-PX2, and the third light emitting areas EA3-PX1, EA3-PX2 may have one of a triangular planar shape, a circular planar shape, a track-shaped planar shape, and/or an elliptical planar shape.

The first pixel PX1 may include a first light emitting element LD1 capable of emitting light, and the second pixel PX2 may include a second light emitting element LD2 capable of emitting light. The first light emitting element LD1 may include a (1-1)-th light emitting element LD1-1 that emits light of a first color, a (1-2)-th light emitting element LD1-2 that emits light of a second color, and a (1-3)-th light emitting element LD1-3 that emits light of a third color. The second light emitting element LD2 may include a (2-1)-th light emitting element LD2-1 that emits light of the first color, a (2-2)-th light emitting element LD2-2 that emits light of the second color, and a (2-3)-th light emitting element LD2-3 that emits light of the third color. For example, the first color may be red, the second color may be green, and the third color may be blue. However, the present disclosure is not limited thereto.

Light of the first color may be emitted from each of the first light emitting areas EA1-PX1 and EA1-PX2. In other words, the (1-1)-th light emitting element LD1-1 that emits light of the first color may be disposed in the first light emitting area EA1-PX1 of the first pixel PX1. In addition, the (2-1)-th light emitting element LD2-1 that emits light of the first color may be disposed in the first light emitting area EA1-PX2 of the second pixel PX2.

Light of the second color may be emitted from each of the second light emitting areas EA2-PX1 and EA2-PX2. In other words, the (1-2)-th light emitting element LD1-2 that emits light of the second color may be disposed in the second light emitting area EA2-PX1 of the first pixel PX1. In addition, the (2-2)-th light emitting element LD2-2 that emits light of the second color may be disposed in the second light emitting area EA2-PX2 of the second pixel PX2.

Light of the third color may be emitted from each of the third light emitting areas EA3-PX1 and EA3-PX2. In other words, the (1-3)-th light emitting element LD1-3 that emits light of the third color may be disposed in the third light emitting area EA3-PX1 of the first pixel PX1. In addition, the (2-3)-th light emitting element LD2-3 that emits light of the third color may be disposed in the third light emitting area EA3-PX2 of the second pixel PX2.

In an embodiment, a size (e.g., an area) of each of the third light emitting areas EA3-PX1 and EA3-PX2 may be greater than a size of each of the second light emitting areas EA2-PX1 and EA2-PX2. In addition, the size of each of the second light emitting areas EA2-PX1 and EA2-PX2 may be greater than a size of each of the first light emitting areas EA1-PX1 and EA1-PX2. However, the present disclosure is not limited thereto, and each of the first light emitting areas EA1-PX1 and EA1-PX2, the second light emitting areas EA2-PX1 and EA2-PX2, and third light emitting areas EA3-PX1 and EA3-PX2 may have the same or substantially the same size as each other.

The first light emitting area EA1-PX1 of the first pixel PX1 may be adjacent to the first light emitting area EA1-PX2 of the second pixel PX2 in the first direction DR1.

The second light emitting area EA2-PX1 of the first pixel PX1 may be adjacent to the second light emitting area EA2-PX2 of the second pixel PX2 in the first direction DR1. The second light emitting area EA2-PX1 of the first pixel PX1 may be spaced apart from the first light emitting area EA1-PX1 of the first pixel PX1 in the second direction DR2. The second light emitting area EA2-PX2 of the second pixel PX2 may be spaced apart from the first light emitting area EA1-PX2 of the second pixel PX2 in the second direction DR2.

The third light emitting area EA3-PX1 of the first pixel PX1 may be adjacent to the third light emitting area EA3-PX2 of the second pixel PX2 in the first direction DR1. The third light emitting area EA3-PX1 of the first pixel PX1 may be spaced apart from the first light emitting area EA1-PX1 of the first pixel PX1 and the second light emitting area EA2-PX1 of the first pixel PX1 in the first direction DR1. The third light emitting area EA3-PX2 of the second pixel PX2 may be spaced apart from the first light emitting area EA1-PX2 of the second pixel PX2 and the second light emitting area EA2-PX2 of the second pixel PX2 in the first direction DR1.

A non-light emitting area NEA may be defined as an area that does not emit light. For example, the non-light emitting area NEA may surround (e.g., around peripheries of) the first light emitting areas EA1-PX1 and EA1-PX2, the second light emitting areas EA2-PX1 and EA2-PX2, and the third light emitting areas EA3-PX1 and EA3-PX2 in a plan view.

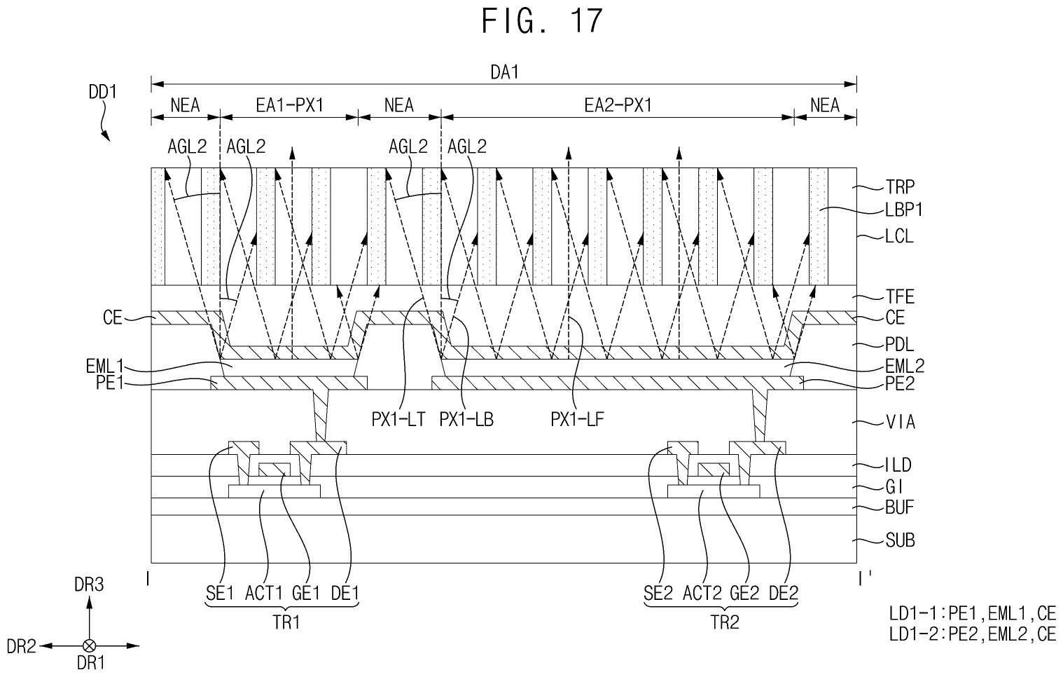

The first light blocking patterns LBP1 may be repeatedly disposed along the second direction DR2 on the substrate SUB in the first display area DA1. The first light blocking patterns LBP1 may be spaced apart from each other in the second direction DR2 in the first display area DA1. Each of the first light blocking patterns LBP1 may extend in the first direction DR1. The first light blocking patterns LBP1 may adjust a viewing angle in the second direction DR2 (e.g., the up-down direction). This will be described in more detail below with reference to FIG. 17.

Referring further to FIG. 3, the display device DD1 according to an embodiment of the present disclosure may include the substrate SUB, a buffer layer BUF, a first thin film transistor TR1, a second thin film transistor TR2, a gate insulating layer GI, an inter-layer insulating layer ILD, a via-insulating layer VIA, the (1-1)-th light emitting element LD1-1, the (1-2)-th light emitting element LD1-2, a pixel defining layer PDL, an encapsulation layer TFE, and a light control layer LCL in the first display area DA1.

The first thin film transistor TR1 may include a first active pattern ACT1, a first gate electrode GE1, a first source electrode SE1, and a first drain electrode DE1. The second thin film transistor TR2 may include a second active pattern ACT2, a second gate electrode GE2, a second source electrode SE2, and a second drain electrode DE2. The (1-1)-th light emitting element LD1-1 may include a first pixel electrode PE1, a first light emitting layer EML1, and a common electrode CE. The (1-2)-th light emitting element LD1-2 may include a second pixel electrode PE2, a second light emitting layer EML2, and the common electrode CE.

The substrate SUB may include a transparent material or an opaque material. The substrate SUB may be formed of a transparent resin substrate. A polyimide substrate may be an example of the transparent resin substrate. In this case, the polyimide substrate may include a first organic layer, a first barrier layer, a second organic layer, and/or the like. As another example, the substrate SUB may include a quartz substrate, a synthetic quartz substrate, a calcium fluoride substrate, a fluorine-doped quartz substrate, a soda-lime glass substrate, a non-alkali glass substrate, and/or the like. These may be used alone or in any suitable combination with each other.

The buffer layer BUF may be disposed on the substrate SUB. The buffer layer BUF may prevent or substantially prevent diffusion of metal atoms or impurities from the substrate SUB to an upper structure (e.g., the (1-1)-th light emitting element LD1-1, the (1-2)-th light emitting element LD1-2, and/or the like). In addition, the buffer layer BUF may serve to improve a flatness of the surface (e.g., the upper surface) of the substrate SUB when the surface of the substrate SUB is not uniform. For example, the buffer layer BUF may include an inorganic insulating material. Examples of the inorganic insulating material that may be used as the buffer layer BUF may include silicon oxide (SiOₓ), silicon nitride (SiNₓ), silicon oxynitride (SiOₓN_{y}), and/or the like. These may be used alone or in any suitable combination with each other.

Each of the first active pattern ACT1 and the second active pattern ACT2 may be disposed on the buffer layer BUF. Each of the first active pattern ACT1 and the second active pattern ACT2 may include an oxide semiconductor, a silicon semiconductor, an organic semiconductor, and/or the like. For example, the oxide semiconductor may include at least one oxide selected from indium (In), gallium (Ga), tin (Sn), zirconium (Zr), vanadium (V), hafnium (Hf), cadmium (Cd), germanium (Ge), chromium (Cr), titanium (Ti), zinc (Zn), and/or the like. The silicon semiconductor may include amorphous silicon, polycrystalline silicon, and/or the like. The first active pattern ACT1 may include a first source area, a first drain area, and a first channel area positioned between the first source area and the first drain area. The second active pattern ACT2 may include a second source area, a second drain area, and a second channel area positioned between the second source area and the second drain area.

The gate insulating layer GI may be disposed on the buffer layer BUF. The gate insulating layer GI may cover the first and second active patterns ACT1 and ACT2 on the buffer layer BUF, and may have a flat or substantially flat upper surface without creating a step difference around the first and second active patterns ACT1 and ACT2. As another example, the gate insulating layer GI may cover the first and second active patterns ACT1 and ACT2 on the buffer layer BUF, and may be disposed along the profile of the first and second active patterns ACT1 and ACT2 with a uniform or substantially uniform thickness. The gate insulating layer GI may include an inorganic insulating material. Examples of the inorganic insulating material that may be used as the gate insulating layer GI may include silicon oxide (SiOₓ), silicon nitride (SiNₓ), silicon oxynitride (SiOₓN_{y}), and/or the like. These may be used alone or in any suitable combination with each other.

Each of the first gate electrode GE1 and the second gate electrode GE2 may be disposed on the gate insulating layer GI. The first gate electrode GE1 may overlap with the first channel area of the first active pattern ACT1. The second gate electrode GE2 may overlap with the second channel area of the second active pattern ACT2.

Each of the first gate electrode GE1 and the second gate electrode GE2 may include a metal, an alloy, a metal nitride, a conductive metal oxide, a transparent conductive material, and/or the like. Examples of the material that may be used as the first and second gate electrodes GE1 and GE2 may include silver (Ag), an alloy including silver, molybdenum (Mo), an alloy including molybdenum, aluminum (AI), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These may be used alone or in any suitable combination with each other.

The inter-layer insulating layer ILD may be disposed on the gate insulating layer GI. The inter-layer insulating layer ILD may cover the first and second gate electrodes GE1 and GE2 on the gate insulating layer GI, and may have a flat or substantially flat upper surface without creating a step difference around the first and second gate electrodes GE1 and GE2. As another example, the inter-layer insulating layer ILD may cover the first and second gate electrodes GE1 and GE2 on the gate insulating layer GI, and may be disposed along the profile of the first and second gate electrodes GE1 and GE2 with a uniform or substantially uniform thickness. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), and/or the like. These may be used alone or in any suitable combination with each other.

Each of the first source electrode SE1, the second source electrode SE2, the first drain electrode DE1, and the second drain electrode DE2 may be disposed on the inter-layer insulating layer ILD. The first source electrode SE1 may be connected to the first source area of the first active pattern ACT1 through a contact hole penetrating the gate insulating layer GI and the inter-layer insulating layer ILD. The first drain electrode DE1 may be connected to the first drain area of the first active pattern ACT1 through a contact hole penetrating the gate insulating layer GI and the inter-layer insulating layer ILD. The second source electrode SE2 may be connected to the second source area of the second active pattern ACT2 through a contact hole penetrating the gate insulating layer GI and the inter-layer insulating layer ILD. The second drain electrode DE2 may be connected to the second drain area of the second active pattern ACT2 through a contact hole penetrating the gate insulating layer GI and the inter-layer insulating layer ILD. Each of the first source electrode SE1, the second source electrode SE2, the first drain electrode DE1, and the second drain electrode DE2 may include a metal, an alloy, a metal nitride, a conductive metal oxide, a transparent conductive material, and/or the like. These may be used alone or in any suitable combination with each other.

Accordingly, the first thin film transistor TR1 including the first active pattern ACT1, the first gate electrode GE1, the first source electrode SE1, and the first drain electrode DE1 may be formed. In addition, the second thin film transistor TR2 including the second active pattern ACT2, the second gate electrode GE2, the second source electrode SE2, and the second drain electrode DE2 may be formed.

The via-insulating layer VIA may be disposed on the inter-layer insulating layer ILD. The via-insulating layer VIA may be disposed on the inter-layer insulating layer ILD with a relatively thicker thickness to sufficiently cover the first and second source electrodes SE1 and SE2 and the first and second drain electrodes DE1 and DE2. The via-insulating layer VIA may include an organic insulating material. Examples of the organic insulating material that may be used as the via-insulating layer VIA may include a photoresist, a polyacryl-based resin, a polyimide-based resin, a polyamide-based resin, a siloxane-based resin, an acryl-based resin, an epoxy-based resin, and/or the like. These may be used alone or in any suitable combination with each other.

Each of the first pixel electrode PE1 and the second pixel electrode PE2 may be disposed on the via-insulating layer VIA. The first pixel electrode PE1 may be connected to the first drain electrode DE1 through a contact hole penetrating the via-insulating layer VIA. Accordingly, the first pixel electrode PE1 may be electrically connected to the first thin film transistor TR1. The second pixel electrode PE2 may be connected to the second drain electrode DE2 through a contact hole penetrating the via-insulating layer VIA. Accordingly, the second pixel electrode PE2 may be electrically connected to the second thin film transistor TR2. Each of the first pixel electrode PE1 and the second pixel electrode PE2 may include a metal, an alloy, a metal nitride, a conductive metal oxide, a transparent conductive material, and/or the like. These may be used alone or in any suitable combination with each other. For example, each of the first pixel electrode PE1 and the second pixel electrode PE2 may serve as an anode electrode.

The pixel defining layer PDL may be disposed on the via-insulating layer VIA. The pixel defining layer PDL may overlap with the non-light emitting area NEA. The pixel defining layer PDL may cover an edge of each of the first pixel electrode PE1 and the second pixel electrode PE2. The pixel defining layer PDL may expose a portion of an upper surface of each of the first pixel electrode PE1 and the second pixel electrode PE2. The pixel defining layer PDL may include an organic insulating material. Examples of the organic insulating material that may be used as the pixel defining layer PDL may include a photoresist, a polyacryl-based resin, a polyimide-based resin, a polyamide-based resin, a siloxane-based resin, an acryl-based resin, an epoxy-based resin, and/or the like. These may be used alone or in any suitable combination with each other.

The first light emitting layer EML1 may be disposed on the first pixel electrode PE1, and the second light emitting layer EML2 may be disposed on the second pixel electrode PE2. In addition, the first light emitting layer EML1 may overlap with the first light emitting area EA1-PX1 of the first pixel PX1, and the second light emitting layer EML2 may overlap with the second light emitting area EA2-PX1 of the first pixel PX1. Each of the first light emitting layer EML1 and the second light emitting layer EML2 may include an organic material that emits light of a desired color (e.g., a preset or predetermined color). For example, the first light emitting layer EML1 may include an organic material that emits red light, and the second light emitting layer EML2 may include an organic material that emits green light. However, the present disclosure is not limited thereto.

The common electrode CE may be disposed on the pixel defining layer PDL, the first light emitting layer EML1, and the second light emitting layer EML2. The common electrode CE may include a metal, an alloy, a metal nitride, a conductive metal oxide, a transparent conductive material, and/or the like. These may be used alone or in any suitable combination with each other. For example, the common electrode CE may serve as a cathode electrode.

Accordingly, the (1-1)-th light emitting element LD1-1 including the first pixel electrode PE1, the first light emitting layer EML1, and the common electrode CE may be formed. In addition, the (1-2)-th light emitting element LD1-2 including the second pixel electrode PE2, the second light emitting layer EML2, and the common electrode CE may be formed.

The encapsulation layer TFE may be disposed on the common electrode CE. The encapsulation layer TFE may prevent or substantially prevent impurities, moisture, and/or the like from penetrating into the (1-1)-th light emitting element LD1-1 and the (1-2)-th light emitting element LD1-2 from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), and/or the like. These may be used alone or in any suitable combination with each other. For example, the organic encapsulation layer may include a cured polymer such as polyacrylate.

The light control layer LCL may be disposed on the encapsulation layer TFE. The light control layer LCL may include the first light blocking patterns LBP1 and transmission patterns TRP. The transmission patterns TRP may surround (e.g., around peripheries of) the first light blocking patterns LBP1. For example, the transmission patterns TRP may overlap with the first light emitting area EA1-PX1 of the first pixel PX1, the second light emitting area EA2-PX1 of the first pixel PX1, and the non-light emitting area NEA. Light emitted from the (1-1)-th light emitting element LD1-1 and the (1-2)-th light emitting element LD1-2 may pass through the transmission patterns TRP. The transmission patterns TRP may include an organic material.

The first light blocking patterns LBP1 may be repeatedly disposed along the second direction DR2, and may be spaced apart from each other by a distance (e.g., a predetermined distance). In an embodiment, a first height H1 of the first light blocking pattern LBP1 may be equal to or substantially equal to a height of the transmission pattern TRP. The first height H1 may refer to a straight-line distance in the third direction DR3 from an upper surface of the encapsulation layer TFE to an upper surface of the first light blocking pattern LBP1. For example, the first height H1 of the first light blocking pattern LBP1 may be about 40 micrometers to about 48 micrometers.

In an embodiment, as illustrated in FIG. 2, some of the first light blocking patterns LBP1 may partially overlap with the first light emitting element LD1 and the second light emitting element LD2 in a plan view. In other words, some of the first light blocking patterns LBP1 may partially overlap with the first light emitting element LD1 and the second light emitting element LD2 in a plan view, and other portions of the first blocking patterns LBP1 may not overlap with the first light emitting element LD1 and the second light emitting element LD2 in a plan view. For example, as illustrated in FIG. 3, some of the first light blocking patterns LBP1 may partially overlap with the (1-1)-th light emitting element LD1-1 and the (1-2)-th light emitting element LD1-2 in a plan view. However, the present disclosure is not limited thereto, and all of the first light blocking patterns LBP1 may partially overlap with the first light emitting element LD1 and the second light emitting element LD2 in a plan view.

In an embodiment, each of the first light blocking patterns LBP1 may include an organic material including a light blocking material having a black color. Accordingly, the first light blocking patterns LBP1 may selectively block some of the light emitted from the first pixel PX1 and the second pixel PX2. For example, the first light blocking patterns LBP1 may selectively block some of the light emitted from the (1-1)-th light emitting element LD1-1 and the (1-2)-th light emitting element LD1-2. In other words, the first light blocking patterns LBP1 may adjust a viewing angle of the display device DD1 by selectively absorbing some of the light emitted from the (1-1)-th light emitting element LD1-1 and the (1-2)-th light emitting element LD1-2. The first light blocking patterns LBP1 may adjust a viewing angle in the second direction DR2 (e.g., the up-down direction).

Although the display device DD1 is described in more detail herein in the context of the organic light emitting display (OLED) device, the present disclosure is not limited thereto. In other embodiments, the display device DD1 may include a liquid crystal display (LCD) device, a field emission display (FED) device, a plasma display panel (PDP) device, an electrophoretic image display (EPD) device, an inorganic light emitting display (ILED) device, or a quantum dot display device.

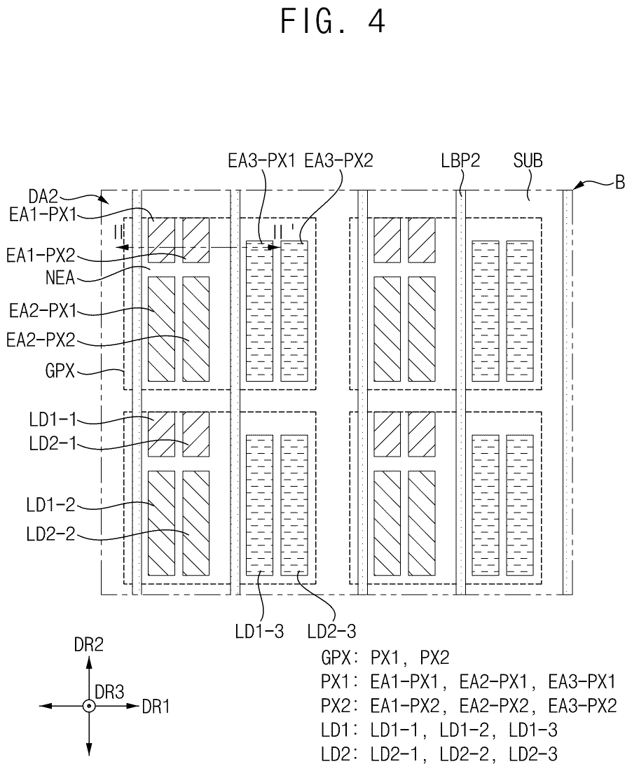

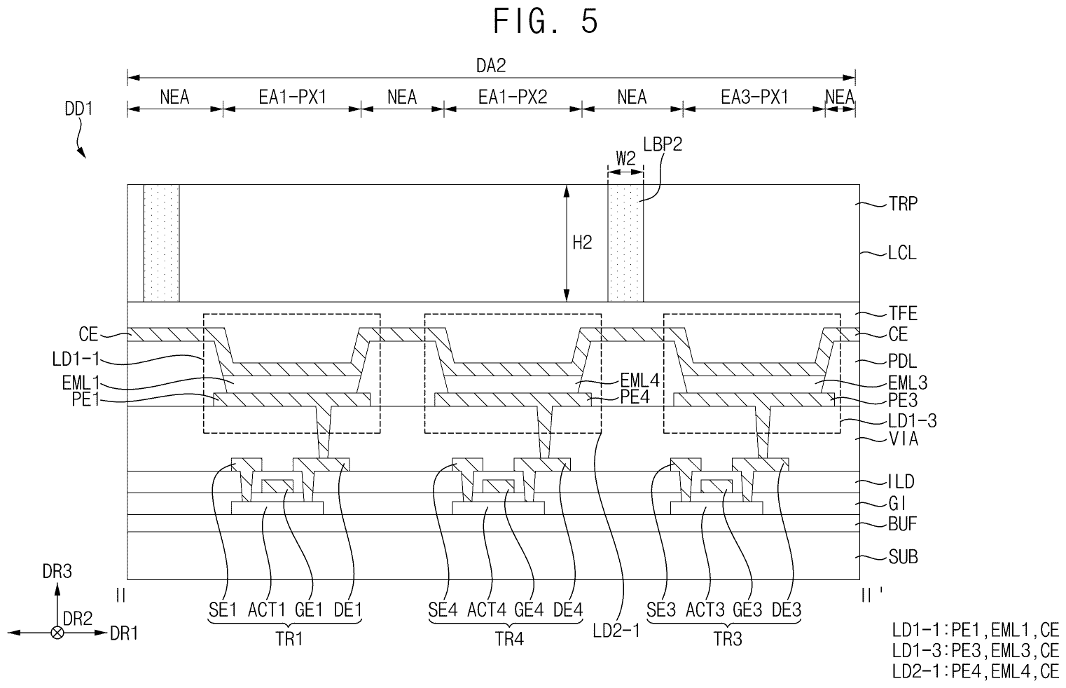

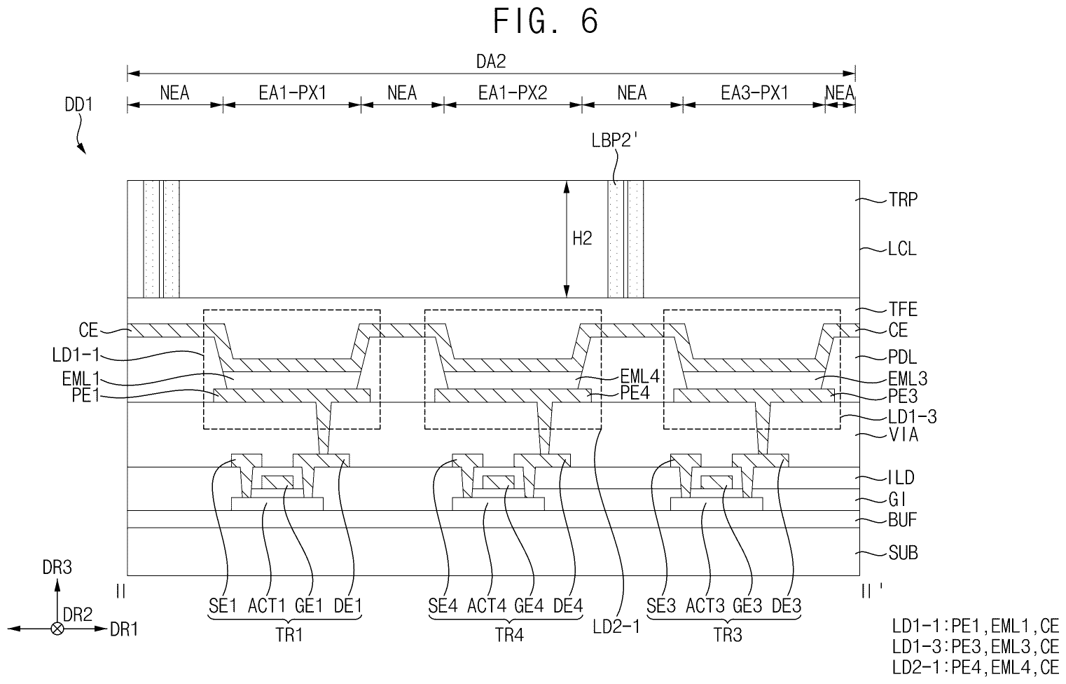

FIG. 4 is an enlarged plan view of the area ‘B’ of FIG. 1. FIG. 5 is a cross-sectional view taken along the line II-II′ of FIG. 4 according to an embodiment of the present disclosure. FIG. 6 is a cross-sectional view taken along the line II-II′ of FIG. 4 according to another embodiment of the present disclosure.

Referring to FIG. 4, the display device DD1 according to an embodiment of the present disclosure may include the substrate SUB, the group pixels GPX, and the second light blocking patterns LBP2 in the second display area DA2. Hereinafter, redundant description with that of the display device DD1 described above with reference to FIG. 2 may not be repeated or may be simplified.

The group pixels GPX may be repeatedly disposed along the first direction DR1 and the second direction DR2 on the substrate SUB in the second display area DA2. Each of the group pixels GPX may include the first pixel PX1 and the second pixel PX2. For example, the first pixel PX1 may correspond to the left pixel of the group pixel GPX, and the second pixel PX2 may correspond to the right pixel of the group pixel GPX.

The second light blocking patterns LBP2 may be repeatedly disposed along the first direction DR1 on the substrate SUB in the second display area DA2. The second light blocking patterns LBP2 may be spaced apart from each other in the first direction DR1 in the second display area DA2. Each of the second light blocking patterns LBP2 may extend in the second direction DR2. In an embodiment, each of the second light blocking patterns LBP2 may be disposed to be adjacent to a corresponding first pixel PX1. In more detail, some of the second light blocking patterns LBP2 may be adjacent to the first light emitting area EA1-PX1 of the first pixel PX1 and the second light emitting area EA2-PX1 of the first pixel PX1 in the first direction DR1. In addition, other portions of the second light blocking patterns LBP2 may be adjacent to the third light emitting area EA3-PX1 of the first pixel PX1 in the first direction DR1.

The second light blocking patterns LBP2 may adjust a viewing angle in the first direction DR1 (e.g., the left-right direction). In more detail, the second light blocking patterns LBP2 may adjust a viewing angle in the left direction or the right direction.

Referring further to FIGS. 3, 5, and 6, the display device DD1 according to an embodiment of the present disclosure may include the substrate SUB, the buffer layer BUF, the first thin film transistor TR1, a third thin film transistor TR3, a fourth thin film transistor TR4, the gate insulating layer GI, the inter-layer insulating layer ILD, the via-insulating layer VIA, the (1-1)-th light emitting element LD1-1, the (1-3)-th light emitting element LD1-3, the (2-1)-th light emitting element LD2-1, the pixel defining layer PDL, the encapsulation layer TFE, and the light control layer LCL in the second display area DA2.

The first thin film transistor TR1 may include the first active pattern ACT1, the first gate electrode GE1, the first source electrode SE1, and the first drain electrode DE1. The third thin film transistor TR3 may include a third active pattern ACT3, a third gate electrode GE3, a third source electrode SE3, and a third drain electrode DE3. The fourth thin film transistor TR4 may include a fourth active pattern ACT4, a fourth gate electrode GE4, a fourth source electrode SE4, and a fourth drain electrode DE4. The (1-1)-th light emitting element LD1-1 may include the first pixel electrode PE1, the first light emitting layer EML1, and the common electrode CE. The (1-3)-th light emitting element LD1-3 may include a third pixel electrode PE3, a third light emitting layer EML3, and the common electrode CE. The (2-1)-th light emitting element LD2-1 may include a fourth pixel electrode PE4, a fourth light emitting layer EML4, and the common electrode CE. Hereinafter, redundant description as that of the display device DD1 described above with reference to FIG. 3 may not be repeated or may be simplified.

The buffer layer BUF may be disposed on the substrate SUB, and each of the first active pattern ACT1, the third active pattern ACT3, and the fourth active pattern ACT4 may be disposed on the buffer layer BUF. The third active pattern ACT3 may include a third source area, a third drain area, and a third channel area positioned between the third source area and the third drain area. The fourth active pattern ACT4 may include a fourth source area, a fourth drain area, and a fourth channel area positioned between the fourth source area and the fourth drain area.

The gate insulating layer GI may be disposed on the buffer layer BUF, and each of the first gate electrode GE1, the third gate electrode GE3, and the fourth gate electrode GE4 may be disposed on the gate insulating layer GI. The third gate electrode GE3 may overlap with the third channel area of the third active pattern ACT3. The fourth gate electrode GE4 may overlap with the fourth channel area of the fourth active pattern ACT4.

The inter-layer insulating layer ILD may be disposed on the gate insulating layer GI, and each of the first source electrode SE1, the third source electrode SE3, the fourth source electrode SE4, the first drain electrode DE1, the third drain electrode DE3, and the fourth drain electrode DE4 may be disposed on the inter-layer insulating layer ILD. The third source electrode SE3 may be connected to the third source area of the third active pattern ACT3. The third drain electrode DE3 may be connected to the third drain area of the third active pattern ACT3. The fourth source electrode SE4 may be connected to the fourth source area of the fourth active pattern ACT4. The fourth drain electrode DE4 may be connected to the fourth drain area of the fourth active pattern ACT4.

Accordingly, the third thin film transistor TR3 including the third active pattern ACT3, the third gate electrode GE3, the third source electrode SE3, and the third drain electrode DE3 may be formed. In addition, the fourth thin film transistor TR4 including the fourth active pattern ACT4, the fourth gate electrode GE4, the fourth source electrode SE4, and the fourth drain electrode DE4 may be formed.

The via-insulating layer VIA may be disposed on the inter-layer insulating layer ILD, and each of the first pixel electrode PE1, the third pixel electrode PE3, and the fourth pixel electrode PE4 may be disposed on the via-insulating layer VIA. In an embodiment, the first pixel electrode PE1 of the (1-1)-th light emitting element LD1-1 may be spaced apart (e.g., separated) from the fourth pixel electrode PE4 of the (2-1)-th light emitting element LD2-1. The third pixel electrode PE3 may be connected to the third drain electrode DE3. Accordingly, the third pixel electrode PE3 may be electrically connected to the third thin film transistor TR3. The fourth pixel electrode PE4 may be connected to the fourth drain electrode DE4. Accordingly, the fourth pixel electrode PE4 may be electrically connected to the fourth thin film transistor TR4.

The pixel defining layer PDL may be disposed on the via-insulating layer VIA. The first light emitting layer EML1 may be disposed on the first pixel electrode PE1, the third light emitting layer EML3 may be disposed on the third pixel electrode PE3, and the fourth light emitting layer EML4 may be disposed on the fourth pixel electrode PE4. The first light emitting layer EML1 may overlap with the first light emitting area EA1-PX1 of the first pixel PX1. The third light emitting layer EML3 may overlap with the third light emitting area EA3-PX1 of the first pixel PX1. The fourth light emitting layer EML4 may overlap with the first light emitting area EA1-PX2 of the second pixel PX2. For example, the third light emitting layer EML3 may include an organic material that emits blue light. Each of the first and fourth light emitting layers EML1 and EML4 may include an organic material that emits red light. However, the present disclosure is not limited thereto.

The common electrode CE may be disposed on the pixel defining layer PDL, the first light emitting layer EML1, the third light emitting layer EML3, and the fourth light emitting layer EML4. Accordingly, the (1-3)-th light emitting element LD1-3 including the third pixel electrode PE3, the third light emitting layer EML3, and the common electrode CE may be formed. In addition, the (2-1)-th light emitting element LD2-1 including the fourth pixel electrode PE4, the fourth light emitting layer EML4, and the common electrode CE may be formed.

The encapsulation layer TFE may be disposed on the common electrode CE, and the light control layer LCL may be disposed on the encapsulation layer TFE. The light control layer LCL may include the second light blocking patterns LBP2 and the transmission patterns TRP. The transmission patterns TRP may surround (e.g., around a periphery of) the second light blocking patterns LBP2. Light emitted from the (1-1)-th light emitting element LD1-1, the (1-3)-th light emitting element LD1-3, and the (2-1)-th light emitting element LD2-1 may pass through the transmission patterns TRP.

The second light blocking patterns LBP2 may be repeatedly disposed along the first direction DR1, and may be spaced apart from each other by a distance (e.g., a 1 predetermined distance). In an embodiment, the second light blocking patterns LBP2 may be disposed in the same layer as that of the first light blocking patterns LBP1. In other words, the first light blocking patterns LBP1 and the second light blocking patterns LBP2 may include the same material as each other, and may be formed through the same process as each other. By concurrently or substantially simultaneously forming the first light blocking patterns LBP1 and the second light blocking patterns LBP2 together through one process, a process efficiency for manufacturing the display device DD1 may be improved. For example, each of the first light blocking patterns LBP1 and the second light blocking patterns LBP2 may be disposed at (e.g., in or on) the light control layer LCL.

In an embodiment, a second height H2 of the second light blocking pattern LBP2 may be equal to or substantially equal to the first height H1 of the first light blocking pattern LBP1. The second height H2 may refer to a straight-line distance in the third direction DR3 from the upper surface of the encapsulation layer TFE to an upper surface of the second light blocking pattern LBP2. For example, the second height H2 of the second light blocking pattern LBP2 may be about 40 micrometers to about 48 micrometers.

In an embodiment, each of the second light blocking patterns LBP2 may include an organic material including a light blocking material having a black color. Accordingly, the second light blocking patterns LBP2 may selectively block some of the light emitted from the first pixel PX1. For example, the second light blocking patterns LBP2 may selectively block some of the light emitted from the (1-1)-th light emitting element LD1-1 and the (1-3)-th light emitting element LD1-3. In other words, the second light blocking patterns LBP2 may adjust a viewing angle of the display device DD1 by selectively absorbing some of the light emitted from the (1-1)-th light emitting element LD1-1 and the (1-3)-th light emitting element LD1-3. The second light blocking patterns LBP2 may adjust a viewing angle in the first direction DR1 (e.g., the left-right direction). In more detail, the second light blocking patterns LBP2 may adjust a viewing angle in the left direction or the right direction. Hereinafter, a case where the second light blocking patterns LBP2 adjust a viewing angle in the left direction may be described in more detail as a representative example.

The second light blocking patterns LBP2 may not block the light emitted from the second pixel PX2 that travel in the left direction. For example, the second light blocking patterns LBP2 may not block the light emitted from the (2-1)-th light emitting element LD2-1 that travel in the left direction.

In an embodiment, the second light blocking patterns LBP2 may be spaced apart from the first light emitting element LD1 and the second light emitting element LD2 in a plan view. In addition, the second light blocking patterns LBP2 may overlap with the pixel defining layer PDL in a plan view. For example, as illustrated in FIGS. 5 and 6, the second light blocking patterns LBP2 may be spaced apart from the (1-1)-th light emitting element LD1-1, the (1-3)-th light emitting element LD1-3, and the (2-1)-th light emitting element LD2-1 in a plan view.

Accordingly, compared to a case where the second light blocking patterns LBP2 overlap with the first light emitting element LD1 and the second light emitting element LD2 in a plan view, the luminance of the display device DD1 may be relatively increased.

As illustrated in FIG. 5, a second width W2 of the second light blocking pattern LBP2 may be greater than a first width W1 of the first light blocking pattern LBP1. Here, the second width W2 may refer to a length of the second light blocking pattern LBP2 in the first direction DR1, and the first width W1 may refer to a length of the first light blocking pattern LBP1 in the second direction DR2. However, the present disclosure is not limited thereto.

In an embodiment, as illustrated in FIG. 5, the pixel defining layer PDL disposed between adjacent light emitting elements that emit light of different colors from each other may overlap with one second light blocking pattern LBP2 in a plan view. For example, the pixel defining layer PDL disposed between the (2-1)-th light 1 emitting element LD2-1 and the (1-3)-th light emitting element LD1-3 may overlap with one second light blocking pattern LBP2 in a plan view. However, the present disclosure is not limited thereto.

In another embodiment, as illustrated in FIG. 6, the pixel defining layer PDL disposed between adjacent light emitting elements that emit light of different colors from each other may overlap with a plurality of second light blocking patterns LBP2′ in a plan view. For example, the pixel defining layer PDL disposed between the (2-1)-th light emitting element LD2-1 and the (1-3)-th light emitting element LD1-3 may overlap with two second light blocking patterns LBP2′ in a plan view. However, the present disclosure is not limited thereto. The pixel defining layer PDL disposed between adjacent light emitting elements that emit light of different colors from each other may overlap with three or more second light blocking patterns LBP2′ in a plan view.

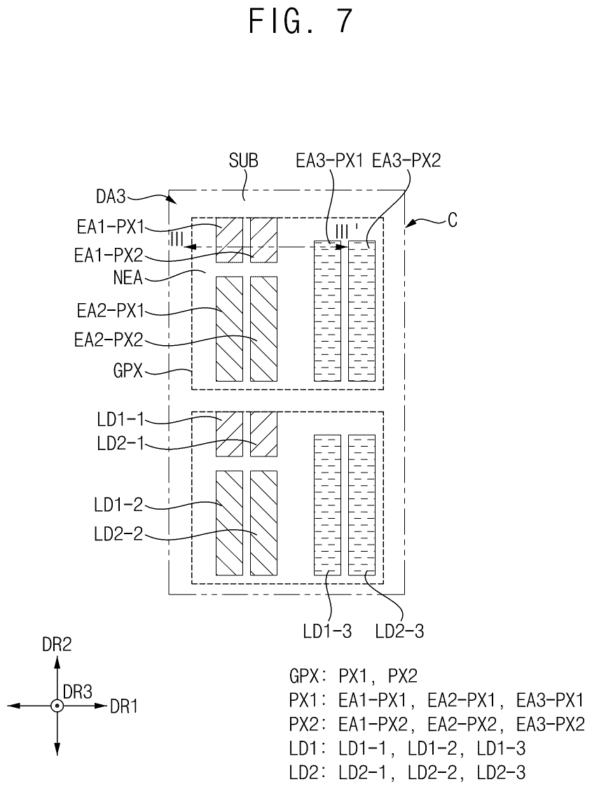

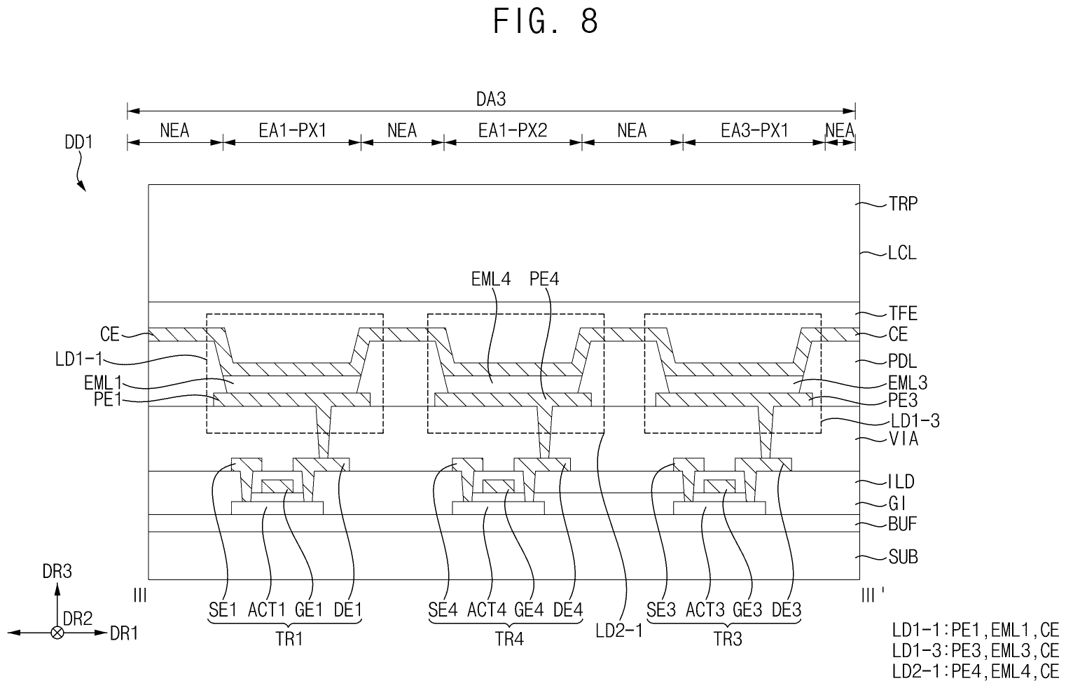

FIG. 7 is an enlarged plan view of the area ‘C’ of FIG. 1. FIG. 8 is a cross-sectional view taken along the line III-III of FIG. 7. Hereinafter, redundant description of the same or substantially the same components as those of the display device DD1 described above with reference to FIGS. 4 and 5 may not be repeated or may be simplified.

Referring to FIG. 7, the display device DD1 according to an embodiment of the present disclosure may include the substrate SUB and the group pixels GPX in the third display area DA3.

The group pixels GPX may be repeatedly disposed along the first direction DR1 and the second direction DR2 on the substrate SUB in the third display area DA3. Each of the group pixels GPX may include the first pixel PX1 and the second pixel PX2. For example, the first pixel PX1 may correspond to the left pixel of the group pixel GPX, and the second pixel PX2 may correspond to the right pixel of the group pixel GPX.

The first light blocking patterns and the second light blocking patterns may be spaced apart from the third display area DA3 in a plan view. In other words, the first light blocking patterns and the second light blocking patterns may not be disposed on the substrate SUB in the third display area DA3.

Referring to FIG. 8, the display device DD1 according to an embodiment of the present disclosure may include the substrate SUB, the buffer layer BUF, the first thin film transistor TR1, the third thin film transistor TR3, the fourth thin film transistor TR4, the gate insulating layer GI, the inter-layer insulating layer ILD, the via-insulating layer VIA, the (1-1)-th light emitting element LD1-1, the (1-3)-th light emitting element LD1-3, the (2-1)-th light emitting element LD2-1, the pixel defining layer PDL, the encapsulation layer TFE, and the light control layer LCL in the third display area DA3.

The light control layer LCL may be disposed on the encapsulation layer TFE. The light control layer LCL may include (e.g., may only include) the transmission pattern TRP in the third display area DA3. In other words, the light control layer LCL may not include a light blocking pattern in the third display area DA3. Light emitted from the (1-1)-th light emitting element LD1-1, the (1-3)-th light emitting element LD1-3, and the (2-1)-th light emitting element LD2-1 may pass through the transmission pattern TRP.

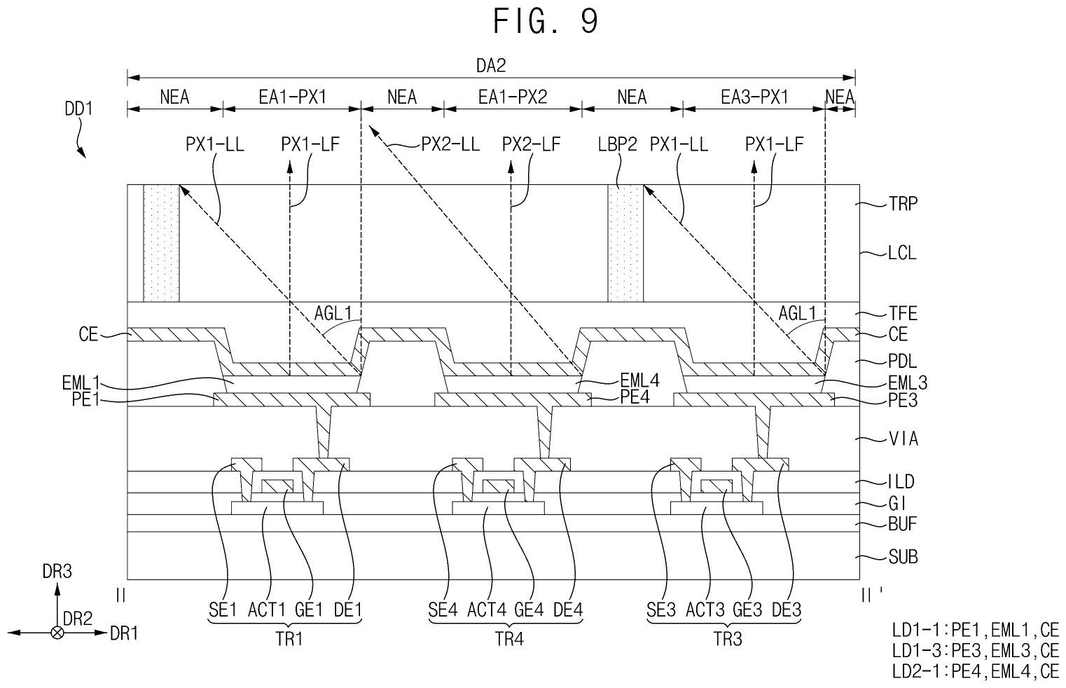

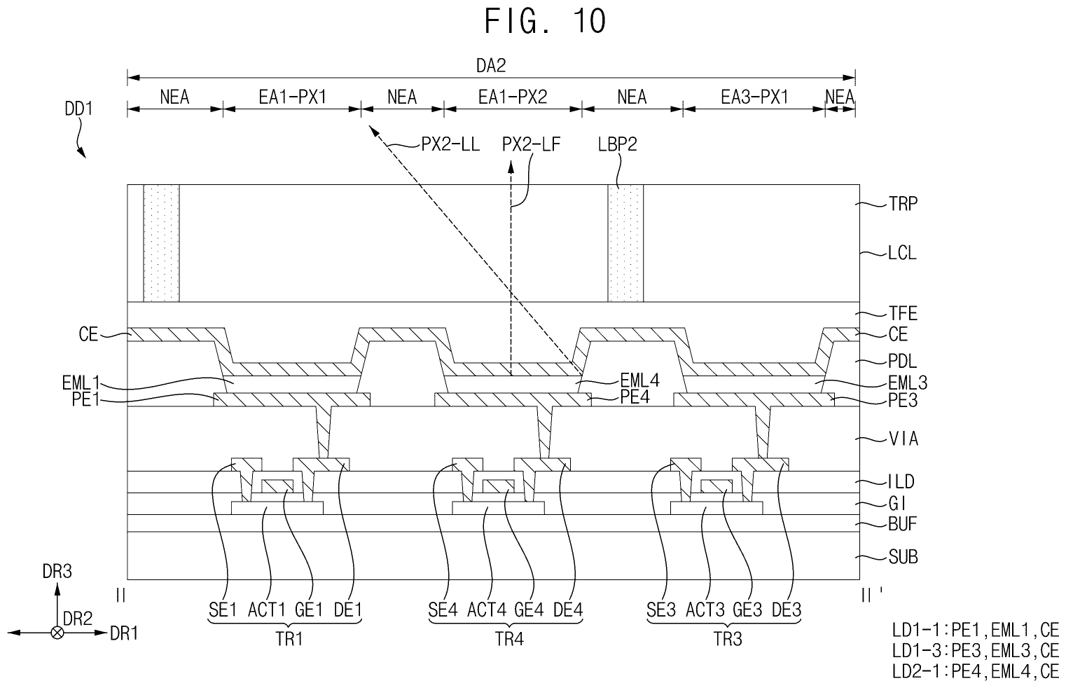

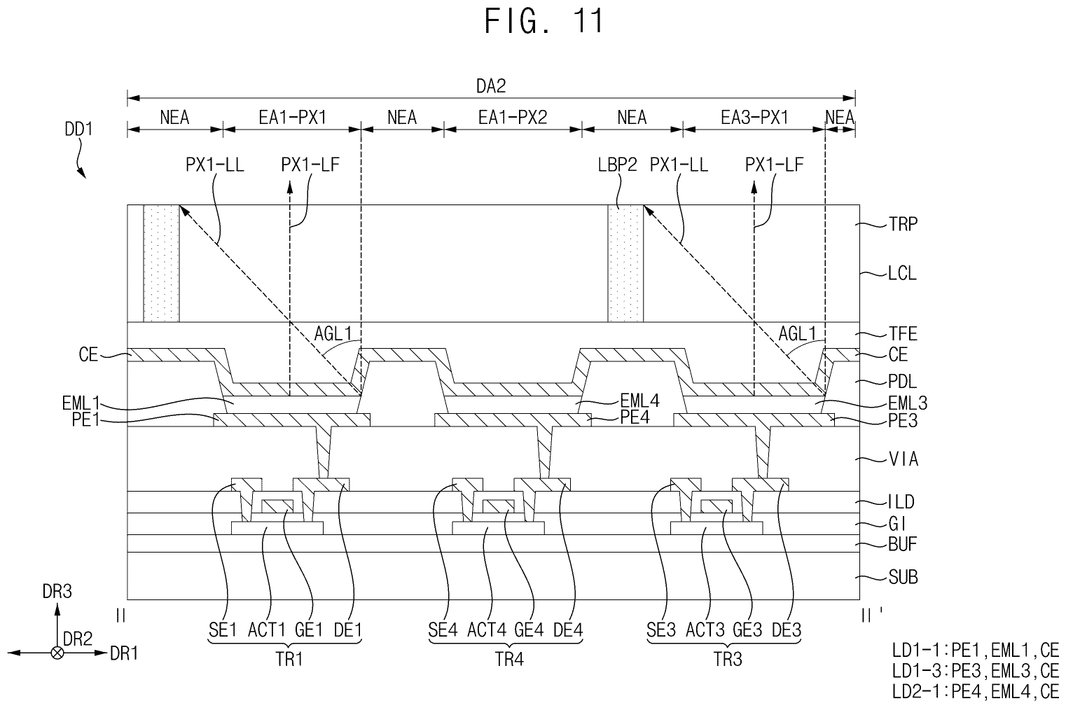

FIGS. 9 through 11 are cross-sectional views taken along the line II-II′ of FIG. 4. For example, FIGS. 9 and 10 are cross-sectional views illustrating the display device DD1 driven in a first mode, and FIG. 11 is a cross-sectional view illustrating the display device DD1 driven in a second mode. The first mode may be defined as a mode that implements a wide viewing angle, and the second mode may be defined as a mode that implements a narrow viewing angle.

Referring to FIGS. 4 and 9, in an embodiment, when the display device DD1 is driven in the first mode, each of the first light emitting element LD1 of the first pixel PX1 and the second light emitting element LD2 of the second pixel PX2 may emit light in the second display area DA2. For example, when the display device DD1 is driven in the first mode, each of the (1-1)-th light emitting element LD1-1, the (1-3)-th light 1 emitting element LD1-3, and the (2-1)-th light emitting element LD2-1 may emit light in the second display area DA2.

For example, the second display area DA2 may be positioned at (e.g., in or on) the right side of the display area (e.g., the right side of the display area DA of FIG. 1). When the display device DD1 is applied to an automotive display device, a passenger seat may be positioned at (e.g., in or on) the front direction of the second display area DA2, and a driver's seat may be positioned at (e.g., in or on) the left direction of the second display area DA2.

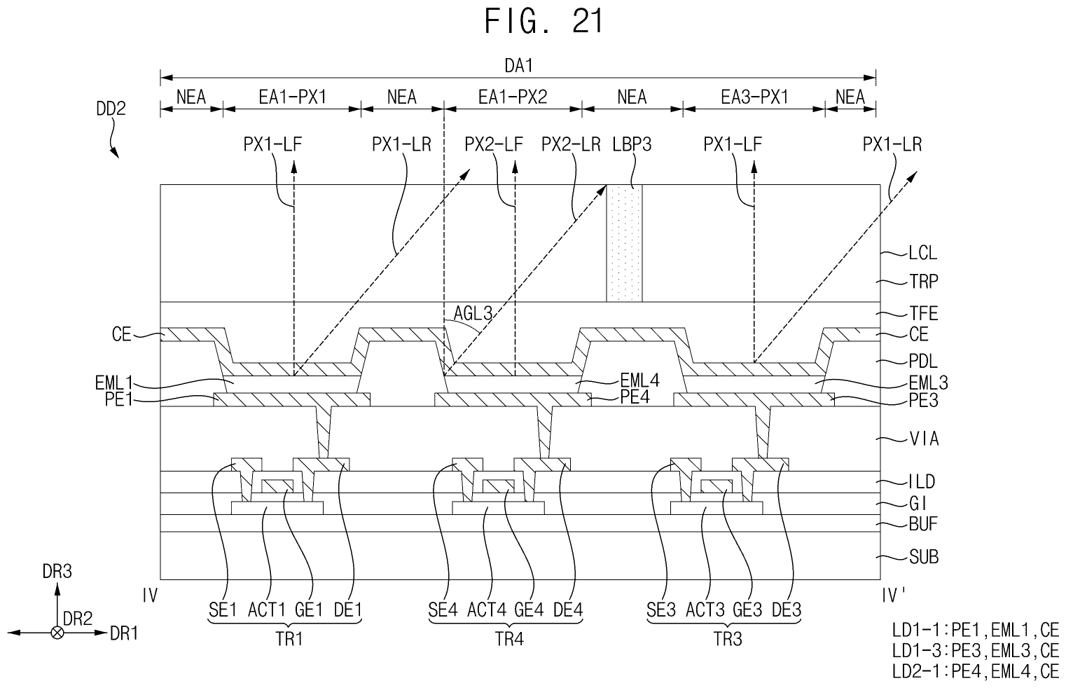

The first light emitting element LD1 may emit first left light PX1-LL traveling in the left direction and first front light PX1-LF traveling in the front direction. For example, each of the (1-1)-th light emitting element LD1-1 and the (1-3)-th light emitting element LD1-3 may emit the first left light PX1-LL and the first front light PX1-LF. The first light emitting element LD1 may further emit first right light (e.g., first right light PX1-LR of FIG. 21) traveling in the right direction, but this will be described in more detail below.

Similarly, the second light emitting element LD2 may emit second left light PX2-LL traveling in the left direction and second front light PX2-LF traveling in the front direction. For example, the (2-1)-th light emitting element LD2-1 may emit the second left light PX2-LL and the second front light PX2-LF. The second light emitting element LD2 may further emit second right light (e.g., second right light PX2-LR of FIG. 21) traveling in the right direction, but this will be described in more detail below.

The second light blocking patterns LBP2 may absorb a portion of the light emitted from the first light emitting element LD1. In more detail, the second light blocking patterns LBP2 may absorb the first left light PX1-LL traveling at an angle greater than a first angle AGL1 in the left direction. In other words, when an angle between an imaginary straight line extending perpendicular or substantially perpendicular to the first light emitting element LD1 and a direction in which the first left light PX1-LL emitted from the first light emitting element LD1 travels is greater than the 1 first angle AGL1, the first left light PX1-LL may be absorbed by the second light blocking patterns LBP2. For example, the first angle AGL1 may be about 45 degrees.

On the other hand, the second light blocking patterns LBP2 may not absorb the second left light PX2-LL emitted from the second light emitting element LD2.

When the display device DD1 is driven in the first mode (e.g., the wide viewing angle mode), a driver positioned at (e.g., in or on) the left direction of the second display area DA2 may view the second left light PX2-LL. Accordingly, the driver may view an image displayed in the second display area DA2. In addition, a passenger positioned at (e.g., in or on) the front direction of the second display area DA2 may view the first front light PX1-LF and the second front light PX2-LF. Accordingly, the passenger may view the image displayed in the second display area DA2.

Referring to FIGS. 4 and 10, in another embodiment, when the display device DD1 is driven in the first mode, the first light emitting element LD1 of the first pixel PX1 may not emit light in the second display area DA2, and the second light emitting element LD2 of the second pixel PX2 may emit light in the second display area DA2. For example, when the display device DD1 is driven in the first mode, each of the (1-1)-th light emitting element LD1-1 and the (1-3)-th light emitting element LD1-3 may not emit light in the second display area DA2, and the (2-1)-th light emitting element LD2-1 may emit light in the second display area DA2.

The second light emitting element LD2 may emit the second left light PX2-LL traveling in the left direction and the second front light PX2-LF traveling in the front direction.

When the display device DD1 is driven in the first mode (e.g., the wide viewing angle mode), a driver positioned at (e.g., in or on) the left direction of the second display area DA2 may view the second left light PX2-LL. Accordingly, the driver may view an image displayed in the second display area DA2. In addition, a passenger positioned at (e.g., in or on) the front direction of the second display area DA2 may view the second front light PX2-LF. Accordingly, the passenger may view the image displayed in the second display area DA2.

Referring to FIGS. 4 and 11, when the display device DD1 is driven in the second mode (e.g., the narrow viewing angle mode), the first light emitting element LD1 of the first pixel PX1 may emit light in the second display area DA2, and the second light emitting element LD2 of the second pixel PX2 may not emit light in the second display area DA2. For example, when the display device DD1 is driven in the second mode, each of the (1-1)-th light emitting element LD1-1 and the (1-3)-th light emitting element LD1-3 may emit light in the second display area DA2, and the (2-1)-th light emitting element LD2-1 may not emit light in the second display area DA2.

The first light emitting element LD1 may emit the first left light PX1-LL traveling in the left direction and the first front light PX1-LF traveling in the front direction.

The second light blocking patterns LBP2 may absorb a portion of the light emitted from the first light emitting element LD1. In more detail, the second light blocking patterns LBP2 may absorb the first left light PX1-LL traveling at an angle greater than the first angle AGL1 in the left direction. In other words, when an angle between the imaginary straight line extending perpendicular or substantially perpendicular to the first light emitting element LD1 and the direction in which the first left light PX1-LL emitted from the first light emitting element LD1 travels is greater than the first angle AGL1, the first left light PX1-LL may be absorbed by the second light blocking patterns LBP2. Accordingly, the second light blocking patterns LBP2 may adjust a viewing angle in the left direction. For example, the first angle AGL1 may be about 45 degrees.

In other words, when the display device DD1 is driven in the second mode (e.g., the narrow viewing angle mode), a driver positioned at (e.g., in or on) the left direction of the second display area DA2 may not view the first left light PX1-LL traveling at an angle greater than the first angle AGL1. Accordingly, the driver may not 1 view an image displayed in the second display area DA2. As a result, the image displayed in the second display area DA2 may not reduce the driver's concentration while driving. On the other hand, a passenger positioned at (e.g., in or on) the front direction of the second display area DA2 may view the first front light PX1-LF. Accordingly, the passenger may view the image displayed in the second display area DA2.

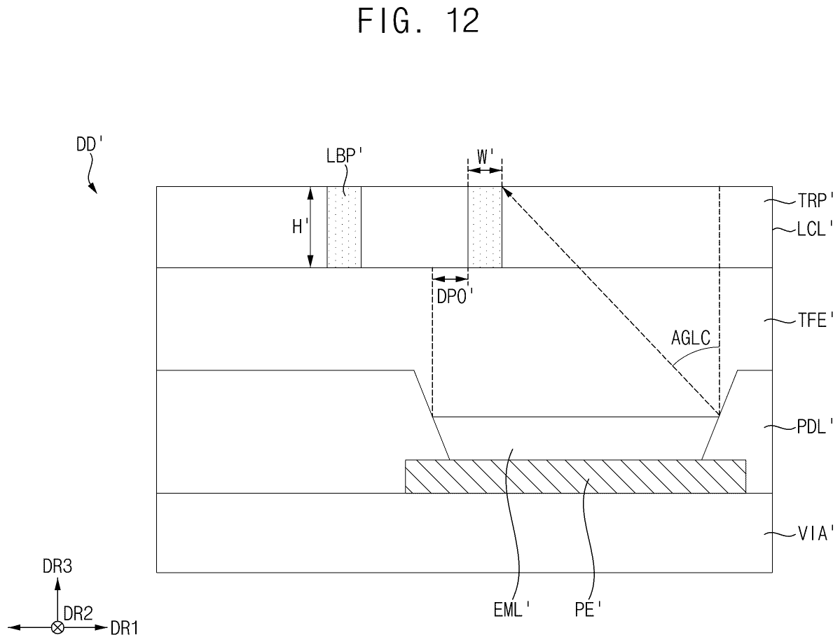

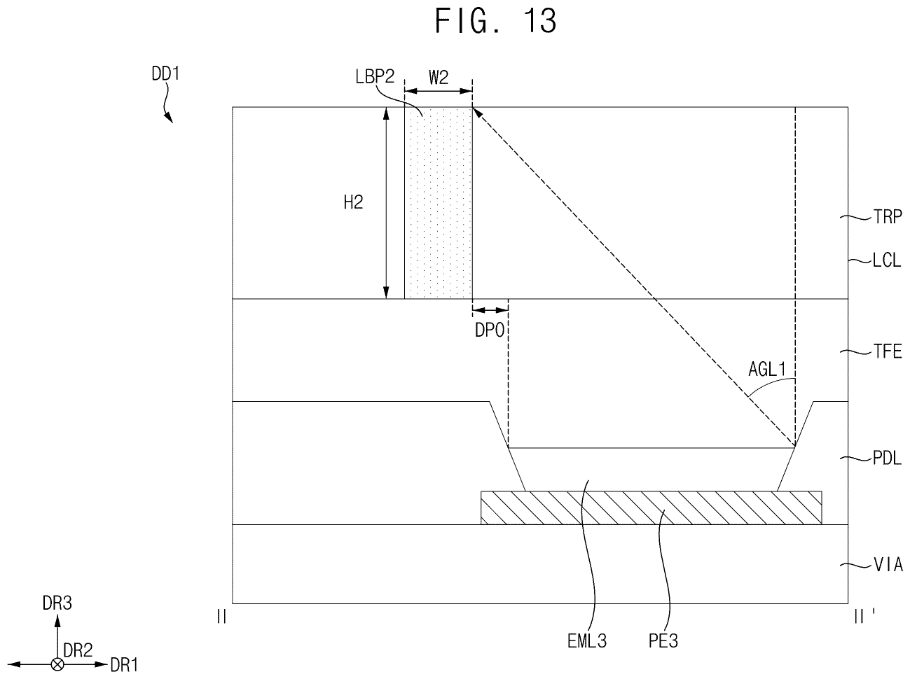

FIG. 12 is a cross-sectional of a display device according to a comparative example. FIG. 13 is a cross-sectional view taken along the line II-II′ of FIG. 4.

Referring to FIG. 12, a display device DD′ according to a comparative example may include a via-insulating layer VIA′, a pixel electrode PE′, a light emitting layer EML′, a pixel defining layer PDL′, an encapsulation layer TFE′, and a light control layer LCL′. Although not illustrated in FIG. 12, the display device DD′ may further include a common electrode disposed on the pixel defining layer PDL′ and the light emitting layer EML′. The display device DD′ may be the same or substantially the same as the display device DD1 described above with reference to FIG. 5, except that a height H′ of a light blocking pattern LBP′ may be different, a width W′ of the light blocking pattern LBP′ may be different, and the light blocking pattern LBP′ overlaps with the light emitting layer EML′ in a plan view.

The light control layer LCL′ may be disposed on the encapsulation layer TFE′. The light control layer LCL′ may include light blocking patterns LBP′ and transmission patterns TRP′. The transmission patterns TRP′ may surround (e.g., around peripheries of) the light blocking patterns LBP′. Light emitted from the light emitting layer EML′ may pass through the transmission patterns TRP′.

The light blocking patterns LBP′ may be repeatedly disposed along the first direction DR1, and spaced apart from each other by a suitable distance (e.g., a predetermined distance). For example, the height H′ of the light blocking pattern LBP′ may be about 28 micrometers to 33 micrometers.

Each of the light blocking patterns LBP′ may include an organic material including a light blocking material having a black color. Accordingly, the light blocking patterns LBP′ may selectively block some of the light emitted from the light emitting layer EML′. In more detail, the light blocking patterns LBP′ may absorb left light traveling at an angle greater than a comparative angle AGLC in the left direction. In other words, when an angle between an imaginary straight line extending perpendicular to the light emitting layer EML′ and a direction in which the left light emitted from the light emitting layer EML′ travels is greater than the comparative angle AGLC, the left light may be absorbed by the light blocking patterns LBP′. For example, the comparative angle AGLC may be about 45 degrees.

Some of the light blocking patterns LBP′ may overlap with the light emitting layer EML′ in a plan view.

Referring to FIG. 13, the display device DD1 according to an embodiment of the present disclosure may include the via-insulating layer VIA, the third pixel electrode PE3, the third light emitting layer EML3, the pixel defining layer PDL, the encapsulation layer TFE, and the light control layer LCL. The display device DD1 may further include the common electrode (e.g., the common electrode CE of FIG. 5) disposed on the pixel defining layer PDL and the light emitting layer EML.

The light control layer LCL may be disposed on the encapsulation layer TFE. The light control layer LCL may include the second light blocking patterns LBP2 and the transmission patterns TRP. The transmission patterns TRP may surround (e.g., around peripheries of) the second light blocking patterns LBP2. Light emitted from the third light emitting layer EML3 may pass through the transmission patterns TRP. The second light blocking patterns LBP2 may be repeatedly disposed along the first direction DR1, and may be spaced apart from each other by a suitable distance (e.g., a predetermined distance).

In an embodiment, the second height H2 of the second light blocking pattern LBP2 may be greater than the height H′ of the light blocking pattern LBP′ illustrated in 1 FIG. 12. For example, the second height H2 may be about 40 micrometers to about 48 micrometers.

Each of the second light blocking patterns LBP2 may include an organic material including a light blocking material having a black color. Accordingly, the second light blocking patterns LBP2 may selectively block some of the light emitted from the third light emitting layer EML3. In more detail, the second light blocking patterns LBP2 may absorb left light traveling at an angle greater than the first angle AGL1 in the left direction. In other words, when an angle between an imaginary straight line extending perpendicular or substantially perpendicular to the third light emitting layer EML3 and a direction in which the left light emitted from the third light emitting layer EML3 travels is greater than the first angle AGL1, the left light may be absorbed by the second light blocking patterns LBP2. For example, the first angle AGL1 may be about 45 degrees.

The second light blocking patterns LBP2 may be spaced apart from the third light emitting layer EML3 in a plan view.

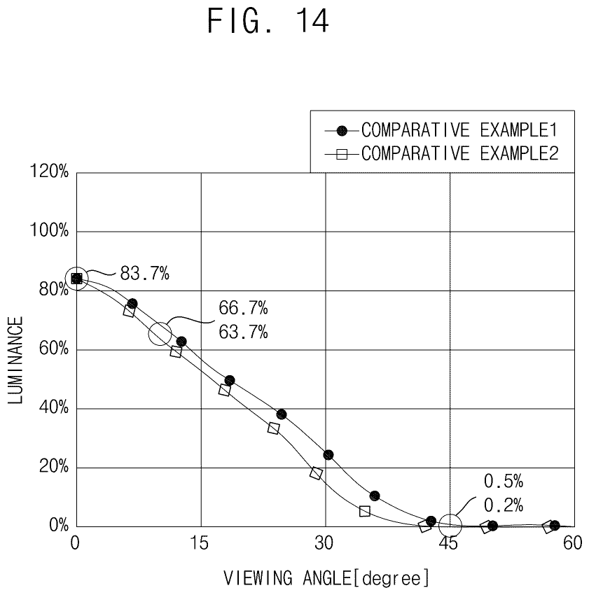

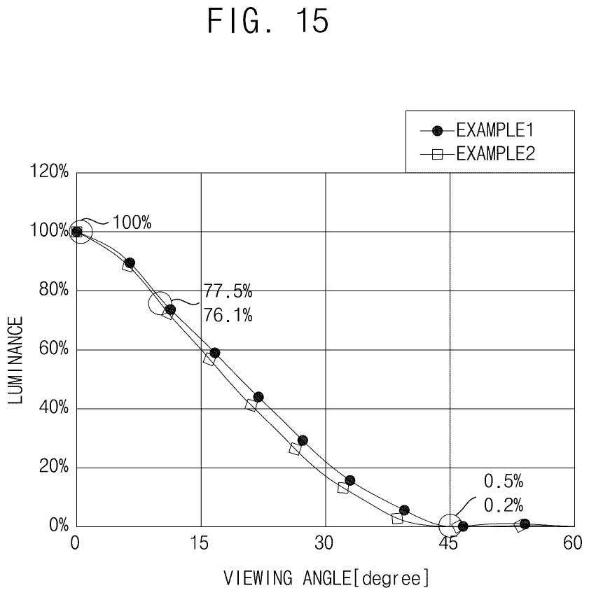

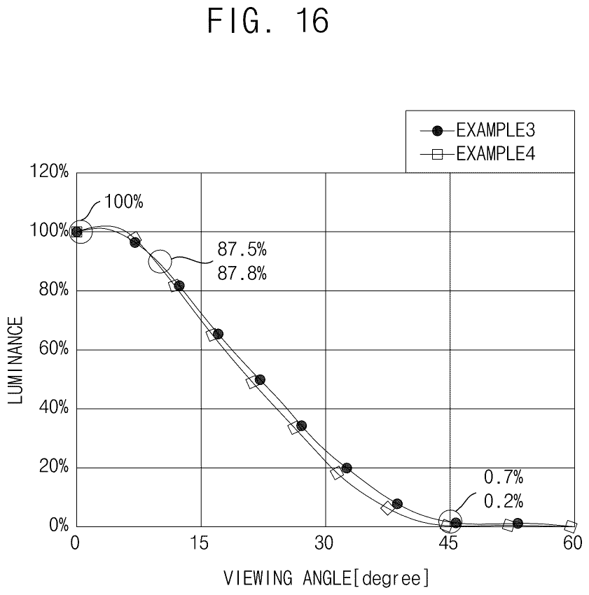

FIG. 14 illustrates a relationship between a viewing angle and a luminance in the display device of FIG. 12. FIGS. 15 and 16 illustrate relationships between a viewing angle and a luminance in the display device of FIG. 13.

Hereinafter, some embodiments of the present disclosure will be described in more detail with reference to FIGS. 12, 13, 14, 15, and 16.

Luminance according to a viewing angle is measured in display devices of a Comparative Example 1, a Comparative Example 2, an Example 1, an Example 2, an Example 3, and an Example 4. The viewing angle may refer to an angle between an imaginary straight line extending perpendicular or substantially perpendicular to a light emitting layer (e.g., a light emitting element) and a direction in which light emitted from the light emitting layer travels to the left.

The display devices of the Example 1 and the Example 2 (e.g., the display device DD1 of FIG. 13) include the second light blocking pattern LBP2 that is spaced 1 apart from the third light emitting layer EML3 in a plan view. The second width W2 of the second light blocking pattern LBP2 is about 17 micrometers. A in-plane separation distance DPO between an edge of the third light emitting layer EML3 and the second light blocking pattern LBP2 is about 1 micrometer. The second height H2 of the second light blocking pattern LBP2 of the display device of the Example 1 is about 40 micrometers. The second height H2 of the second light blocking pattern LBP2 of the display device of the Example 2 is about 44 micrometers.

The display devices of the Example 3 and the Example 4 (e.g., the display device DD1 of FIG. 13) include the second light blocking pattern LBP2 that is spaced apart from the third light emitting layer EML3 in a plan view. The second width W2 of the second light blocking pattern LBP2 is about 14 micrometers. A in-plane separation distance DPO between an edge of the third light emitting layer EML3 and the second light blocking pattern LBP2 is about 4 micrometers. The second height H2 of the second light blocking pattern LBP2 of the display device of the Example 3 is about 45 micrometers. The second height H2 of the second light blocking pattern LBP2 of the display device of the Example 4 is about 48 micrometers.

The display devices of the Comparative Example 1 and the Comparative Example 2 (e.g., the display device DD′ of FIG. 12) include the light blocking pattern LBP′ overlapping with the light emitting layer EML′ in a plan view. The width W′ of the light blocking pattern LBP′ is about 4 micrometers. A in-plane separation distance DPO′ between the light blocking pattern LBP′ overlapping with the light emitting layer EML′ and an edge of the light emitting layer EML′ is about 5.5 micrometers.

The height H′ of the light blocking pattern LBP′ of the display device of the Comparative Example 1 is about 28 micrometers. The height H′ of the light blocking pattern LBP′ of the display device of the Comparative Example 2 is about 33 micrometers.

As illustrated in FIGS. 14, 15, and 16, based on the luminance in a front direction (e.g., a direction in which the viewing angle is about 0 degrees) of the display 1 devices of the Example 1, the Example 2, the Example 3, and the Example 4, the luminance in the front direction of the display devices of the Comparative Example 1 and the Comparative Example 2 is measured to have a value of about 83.7%.

When the viewing angle is about 10 degrees, the luminance of the display device of the Comparative Example 1 is measured to have a value of about 66.7%, and the luminance of the display device of the Comparative Example 2 is measured to have a value of about 63.7%. When the viewing angle is about 10 degrees, the luminance of the display device of the Example 1 is measured to have a value of about 77.5%, and the luminance of the display device of the Example 2 is measured to have a value of about 76.1%. When the viewing angle is about 10 degrees, the luminance of the display device of the Example 3 is measured to have a value of about 87.5%, and the luminance of the display device of the Example 4 is measured to have a value of about 87.8%.

When the viewing angle is about 45 degrees, the luminance of the display devices of the Comparative Example 1, the Comparative Example 2, the Example 1, the Example 2, the Example 3, and the Example 4 is measured to converge to a value of about 0%.

As shown from these results, by including the second light blocking pattern LBP2 that is spaced apart from the third light emitting layer EML in a plan view, the luminance of the display devices DD1 according to embodiments of the present disclosure is relatively increased.

In addition, the in-plane separation distance DPO in the display devices of the Example 3 and the Example 4 may be greater than the in-plane separation distance DPO in the display devices of the Example 1 and the Example 2. Accordingly, when the viewing angle is about 0 degrees to about 15 degrees, the luminance of the display devices of the Example 3 and the Example 4 is relatively more increased than the luminance of the display devices of the Example 1 and the Example 2. In order to design the in-plane separation distance DPO to be relatively large, the second height H2 of the second light blocking pattern LBP2 may be designed to be relatively large.

FIG. 17 is a cross-sectional view taken along the line I-I′ of FIG. 2. For example, FIG. 17 is a cross-sectional view illustrating an absorption of light by the first light blocking patterns LBP1.

Referring to FIGS. 2 and 17, the first light emitting element LD1 of the first pixel PX1 may emit light in the first display area DA1. For example, each of the (1-1)-th light emitting element LD1-1 and the (1-2)-th light emitting element LD1-2 may emit light in the first display area DA1. The second light emitting element LD2 of the second pixel PX2 may also emit light in the first display area DA1. Hereinafter, the first light emitting element LD1 may be described in more detail, and redundant description with respect to the second light emitting element LD2 may not be repeated.

For example, the first display area DA1 may be positioned at (e.g., in or on) the left side of the display area (e.g., of the display area DA of FIG. 1). When the display device DD1 is applied to an automotive display device, a driver's seat may be positioned at (e.g., in or on) the front direction of the first display area DA1.

The first light emitting element LD1 may emit first upper light PX1-LT traveling in the upward direction, first front light PX1-LF traveling in the front direction, and first lower light PX1-LB traveling in the downward direction. For example, each of the (1-1)-th light emitting element LD1-1 and the (1-2)-th light emitting element LD1-2 may emit the first upper light PX1-LT, the first front light PX1-LF, and the first lower light PX1-LB.

Similarly, the second light emitting element LD2 may emit second upper light traveling in the upward direction, second front light traveling in the front direction, and second lower light traveling in the downward direction.

The first light blocking patterns LBP1 may absorb some of the light emitted from the first light emitting element LD1 and the second light emitting element LD2. In more detail, the first light blocking patterns LBP1 may absorb the first upper light PX1-LT traveling at an angle greater than a second angle AGL2 in the upward direction. In other words, when an angle between an imaginary straight line extending perpendicular or substantially perpendicular to the first light emitting element LD1 and a direction in which the first upper light PX1-LT emitted from the first light emitting element LD1 travels is greater than the second angle AGL2, the first upper light PX1-LT may be absorbed by the first light blocking patterns LBP1. Accordingly, the first light blocking patterns LBP1 may adjust a viewing angle in the upward direction. For example, the second angle AGL2 may be about 30 degrees.

In addition, the first light blocking patterns LBP1 may absorb the first lower light PX1-LB traveling at an angle greater than the second angle AGL2 in the downward direction. In other words, when an angle between the imaginary straight line extending perpendicular or substantially perpendicular to the first light emitting element LD1 and a direction in which the first lower light PX1-LB emitted from the first light emitting element LD1 travels is greater than the second angle AGL2, the first lower light PX1-LB may be absorbed by the first light blocking patterns LBP1. Accordingly, the first light blocking patterns LBP1 may adjust a viewing angle in the downward direction.

In other words, the first light blocking patterns LBP1 may adjust the viewing angle in the up-down direction. In more detail, the first light blocking patterns LBP1 may adjust the viewing angle in the up-down direction when the display device DD1 is driven in the second mode (e.g., the narrow viewing angle mode), and the first light blocking patterns LBP1 may adjust the viewing angle in the up-down direction when the display device DD1 is driven in the first mode (e.g., the wide viewing angle mode). As a result, a problem that an image displayed in the first display area DA1 is reflected on a front windshield of the automobile, which may interfere with the driver's operation, may be suppressed.

For example, the first and second pixels PX1 and PX2 disposed in the first display area DA1 may be driven independently from the first and second pixels PX1 and PX2 disposed in the second display area DA2. In other words, even if the display device DD1 is driven in the second mode (e.g., the narrow viewing angle mode), each of the first light emitting element LD1 of the first pixel PX1 and the second light emitting element LD2 of the second pixel PX2 may emit light in the first display area DA1. However, the present disclosure is not limited thereto.

As another example, the first pixel PX1 disposed in the first display area DA1 may be driven together with the first pixel PX1 disposed in the second display area DA2, and the second pixel PX2 disposed in the first display area DA1 may be driven together with the second pixel PX2 disposed in the second display area DA2. In other words, when the display device DD1 is driven in the second mode, the first light emitting element LD1 of the first pixel PX1 may emit light in the first display area DA1, and the second light emitting element LD2 of the second pixel PX2 may not emit light in the first display area DA1.

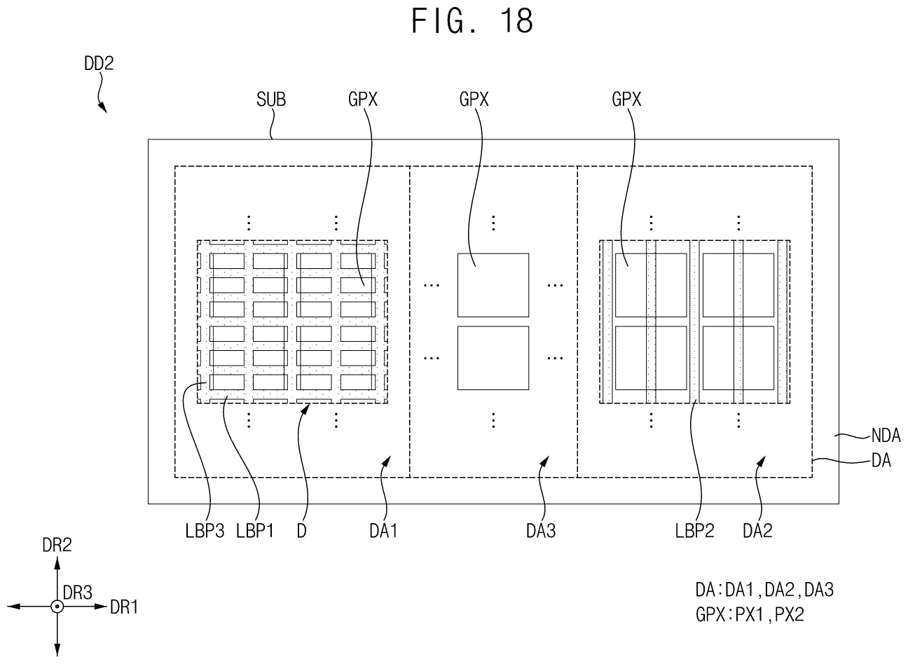

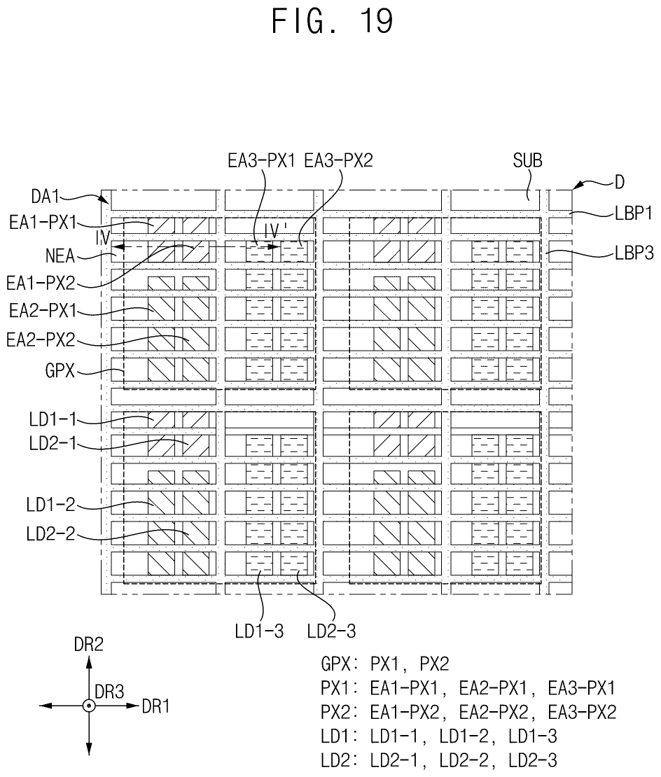

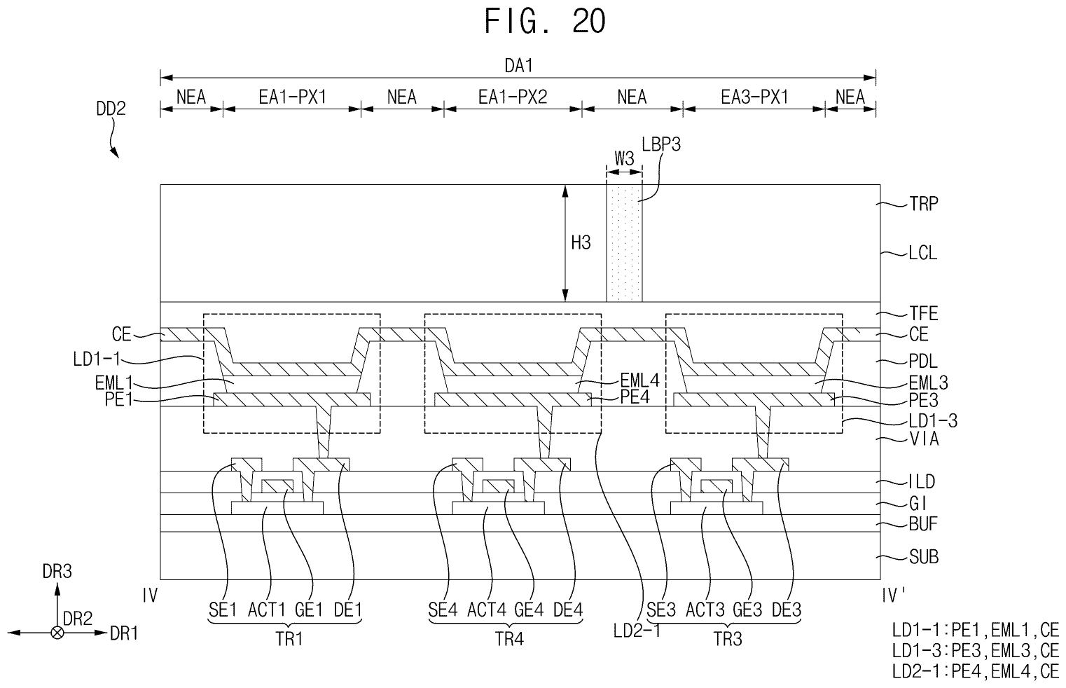

FIG. 18 is a plan view illustrating a display device according to another embodiment of the present disclosure. FIG. 19 is an enlarged plan view of the area ‘D’ of FIG. 18. FIG. 20 is a cross-sectional view taken along the line IV-IV′ of FIG. 19.

Referring to FIGS. 18 and 19, a display device DD2 according to another embodiment of the present disclosure may include the substrate SUB, the group pixels GPX, the first light blocking patterns LBP1, the second light blocking patterns LBP2, and third light blocking patterns LBP3.

The display device DD2 may be the same or substantially the same as the display device DD1 described above with reference to FIGS. 1 to 17, except that the display device DD2 may further include the third light blocking patterns LBP3 in the first display area DA1. Hereinafter, redundant description of the same or substantially the same components as those of the display device DD1 described above with reference to FIGS. 1 to 17 may not be repeated or may be simplified.

The group pixels GPX may be repeatedly disposed along the first direction DR1 and the second direction DR2 on the substrate SUB in the first display area DA1. Each of the group pixels GPX may include the first pixel PX1 and the second pixel PX2. For example, the first pixel PX1 may correspond to the left pixel of the group pixel GPX, and the second pixel PX2 may correspond to the right pixel of the group pixel GPX.

The third light blocking patterns LBP3 may be repeatedly disposed along the first direction DR1 on the substrate SUB in the first display area DA1. The third light blocking patterns LBP3 may be spaced apart from each other in the first direction DR1 in the first display area DA1. Each of the third light blocking patterns LBP3 may extend in the second direction DR2.

In an embodiment, each of the third light blocking patterns LBP3 may be disposed adjacent to a corresponding second pixel PX2. In more detail, some of the third light blocking patterns LBP3 may be adjacent to the first light emitting area EA1-PX2 of the second pixel PX2 and the second light emitting area EA2-PX2 of the second pixel PX2 in the first direction DR1. In addition, other portions of the third light blocking patterns LBP3 may be adjacent to the third light emitting area EA3-PX2 of the second pixel PX2 in the first direction DR1.

The third light blocking patterns LBP3 may adjust a viewing angle in the first direction DR1 (e.g., the left-right direction). In more detail, the third light blocking patterns LBP3 may adjust a viewing angle in the left direction or the right direction.

Referring further to FIG. 20, the display device DD2 according to another embodiment of the present disclosure may include the substrate SUB, the buffer layer BUF, the first thin film transistor TR1, the third thin film transistor TR3, the fourth thin film transistor TR4, the gate insulating layer GI, the inter-layer insulating layer ILD, the via-insulating layer VIA, the (1-1)-th light emitting element LD1-1, the (1-3)-th light emitting element LD1-3, the (2-1)-th light emitting element LD2-1, the pixel defining layer PDL, the encapsulation layer TFE, and a light control layer LCL in the first display area DA1.

The light control layer LCL may be disposed on the encapsulation layer TFE. The light control layer LCL may include the third light blocking patterns LBP3 and transmission patterns TRP. The transmission patterns TRP may surround (e.g., around peripheries of) the third light blocking patterns LBP3. Light emitted from the (1-1)-th light emitting element LD1-1, the (1-3)-th light emitting element LD1-3, and the (2-1)-th light emitting element LD2-1 may pass through the transmission patterns TRP. The third light blocking patterns LBP3 may be repeatedly disposed along the first direction DR1, and may be spaced apart from each other by a suitable distance (e.g., a predetermined distance).

In an embodiment, the third light blocking patterns LBP3 may be disposed in the same layer as that of the first light blocking patterns LBP1 and the second light blocking patterns LBP2. In other words, the first light blocking patterns LBP1, the second light blocking patterns LBP2, and the third light blocking patterns LBP3 may include the same material as each other and may be formed through the same process. Accordingly, a process efficiency for manufacturing the display device DD2 may be improved.

In an embodiment, a third height H3 of the third light blocking pattern LBP3 may be equal to or substantially equal to the first height (e.g., the first height H1 of FIG. 3) of the first light blocking pattern LBP1 and the second height (e.g., the second height H2 of FIG. 5) of the second light blocking pattern LBP2. The third height H3 may refer to a straight-line distance in the third direction DR3 from the upper surface of the encapsulation layer TFE to an upper surface of the third light blocking pattern LBP3. For example, the third height H3 of the third light blocking pattern LBP3 may be about 40 micrometers to about 48 micrometers.

In an embodiment, each of the third light blocking patterns LBP3 may include an organic material including a light blocking material having a black color. Accordingly, the third light blocking patterns LBP3 may selectively block some of the light emitted from the second pixel PX2. For example, the third light blocking patterns LBP3 may selectively block some of the light emitted from the (2-1)-th light emitting element LD2-1. In other words, the third light blocking patterns LBP3 may adjust a viewing angle of the display device DD2 by selectively absorbing some of the light emitted from the (2-1)-th light emitting element LD2-1. The third light blocking patterns LBP3 may adjust a viewing angle in the first direction DR1 (e.g., the left-right direction). In more detail, the third light blocking patterns LBP3 may adjust a viewing angle in the left direction or the right direction. Hereinafter, a case where the third light blocking patterns LBP3 adjust a viewing angle in the right direction may be described in more detail as a representative example.

The third light blocking patterns LBP3 may not block the light emitted from the first pixel PX1 that travels in the right direction. For example, the third light blocking patterns LBP3 may not block the light emitted from the (1-1)-th light emitting element LD1-1 and the (1-3)-th light emitting element LD1-3 that travel in the right direction.

In an embodiment, the third light blocking patterns LBP3 may be spaced apart from the first light emitting element LD1 and the second light emitting element LD2 in a plan view. In addition, the third light blocking patterns LBP3 may overlap with the pixel defining layer PDL in a plan view. For example, the third light blocking patterns LBP3 may be spaced apart from the (1-1)-th light emitting element LD1-1, the (1-3)-th light emitting element LD1-3, and the (2-1)-th light emitting element LD2-1 in a plan view. Accordingly, when compared to a case in which the third light blocking patterns LBP3 overlap with the first light emitting element LD1 and the second light emitting element LD2 in a plan view, the luminance of the display device DD2 may be relatively increased.

For example, a third width W3 of the third light blocking pattern LBP3 may be greater than the first width (e.g., the first width W1 of FIG. 3) of the first light blocking pattern LBP1. The third width W3 may refer to a length of the third light blocking pattern LBP3 in the first direction DR1, and the first width may refer to a length of the first light blocking pattern LBP1 in the second direction DR2. However, the present disclosure is not limited thereto.

The third width W3 of the third light blocking pattern LBP3 may be equal to or substantially equal to the second width (e.g., the second width W2 of FIG. 5) of the second light blocking pattern LBP2. The second width may refer to a length of the second light blocking pattern LBP2 in the first direction DR1. However, the present disclosure is not limited thereto.

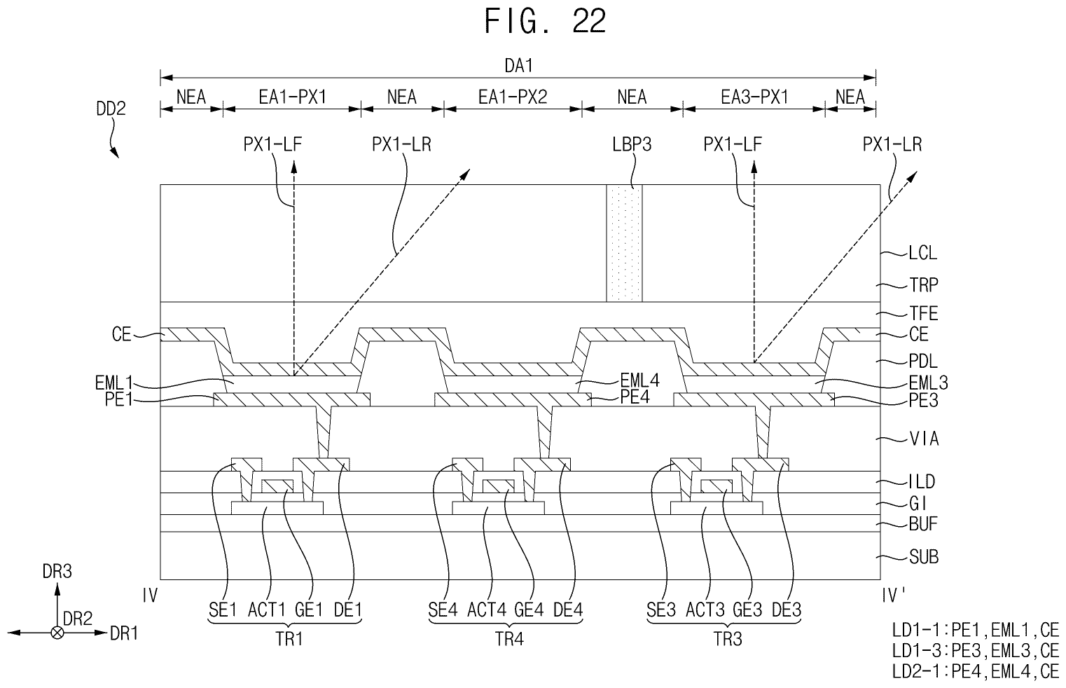

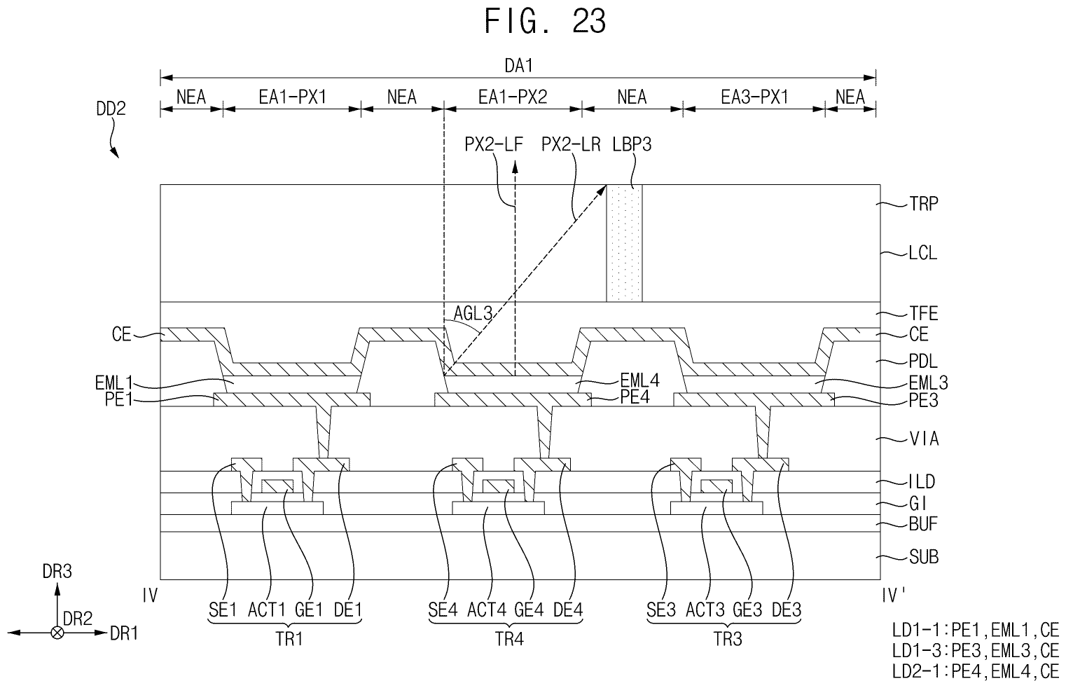

FIGS. 21 through 23 are cross-sectional views taken along the line IV-IV′ of FIG. 19. For example, FIGS. 21 and 22 are cross-sectional views illustrating the display device DD2 driven in a first mode, and FIG. 23 is a cross-sectional view illustrating the display device DD2 driven in a second mode. The first mode may be defined as a mode that implements a wide viewing angle, and the second mode may be defined as a mode that implements a narrow viewing angle.

Referring to FIGS. 19 and 21, in an embodiment, when the display device DD2 is driven in the first mode, each of the first light emitting element LD1 of the first pixel PX1 and the second light emitting element LD2 of the second pixel PX2 may emit light in the first display area DA1. For example, when the display device DD2 is driven in the first mode, each of the (1-1)-th light emitting element LD1-1, the (1-3)-th light emitting element LD1-3, and the (2-1)-th light emitting element LD2-1 may emit light in the first display area DA1.

For example, the first display area DA1 may be positioned at (e.g., in or on) the left side of the display area (e.g., the display area DA of FIG. 18). When the display device DD2 is applied to an automotive display device, a driver's seat may be positioned at (e.g., in or on) the front direction of the first display area DA1, and a passenger seat may be positioned at (e.g., in or on) the right direction of the first display area DA1.

The first light emitting element LD1 may emit first right light PX1-LR traveling in the right direction and first front light PX1-LF traveling in the front direction. For example, each of the (1-1)-th light emitting element LD1-1 and the (1-3)-th light emitting element LD1-3 may emit the first right light PX1-LR and the first front light PX1-LF. The first light emitting element LD1 may further emit first left light (e.g., the first left light PX1-LL of FIG. 9) traveling in the left direction, but redundant description thereof may not be repeated.

Similarly, the second light emitting element LD2 may emit second right light PX2-LR traveling in the right direction and second front light PX2-LF traveling in the front direction. For example, the (2-1)-th light emitting element LD2-1 may emit the second right light PX2-LR and the second front light PX2-LF. The second light emitting element LD2 may further emit second left light (e.g., the second left light PX2-LL of FIG. 9) traveling in the left direction, but redundant description thereof may not be repeated.

The third light blocking patterns LBP3 may absorb a portion of the light emitted from the second light emitting element LD2. In more detail, the third light blocking patterns LBP3 may absorb the second right light PX2-LR traveling at an angle greater than a third angle AGL3 in the right direction. In other words, when an angle between an imaginary straight line extending perpendicular or substantially perpendicular to the second light emitting element LD2 and a direction in which the second right light PX2-LR emitted from the second light emitting element LD2 travels is greater than the third angle AGL3, the second right light PX2-LR may be absorbed by the third light blocking patterns LBP3. In an embodiment, the third angle AGL3 may be equal to or substantially equal to the first angle (e.g., the first angle AGL1 of FIG. 9). However, the present disclosure is not limited thereto. For example, the third angle AGL3 may be about 45 degrees.

On the other hand, the third light blocking patterns LBP3 may not absorb the first right light PX1-LR emitted from the first light emitting element LD1.

When the display device DD2 is driven in the first mode (e.g., the wide viewing angle mode), a passenger positioned at (e.g., in or on) the right direction of the first display area DA1 may view the first right light PX1-LR. Accordingly, the passenger may view an image displayed in the first display area DA1. In addition, a driver positioned at (e.g., in or on) the front direction of the first display area DA1 may view the first front light PX1-LF and the second front light PX2-LF. Accordingly, the driver may view the image displayed in the first display area DA1.

Referring to FIGS. 19 and 22, in another embodiment, when the display device DD2 is driven in the first mode, the first light emitting element LD1 of the first pixel PX1 may emit light in the first display area DA1, and the second light emitting element LD2 of the second pixel PX2 may not emit light in the first display area DA1. For example, when the display device DD2 is driven in the first mode, each of the (1-1)-th light emitting element LD1-1 and the (1-3)-th light emitting element LD1-3 may emit light in the first display area DA1, and the (2-1)-th light emitting element LD2-1 may not emit light in the first display area DA1.

The first light emitting element LD1 may emit the first right light PX1-LR traveling in the right direction and the first front light PX1-LF traveling in the front direction.

When the display device DD2 is driven in the first mode (e.g., the wide viewing angle mode), a passenger positioned at (e.g., in or on) the right direction of the first display area DA1 may view the first right light PX1-LR. Accordingly, the passenger may view an image displayed in the first display area DA1. In addition, a driver positioned at (e.g., in or on) the front direction of the first display area DA1 may view the first front light PX1-LF. Accordingly, the driver may view the image displayed in the first display area DA1.

Referring to FIGS. 19 and 23, when the display device DD2 is driven in the second mode (e.g., the narrow viewing angle mode), the first light emitting element LD1 of the first pixel PX1 may not emit light in the first display area DA1, and the second light emitting element LD2 of the second pixel PX2 may emit light in the first display area DA1. For example, when the display device DD2 is driven in the second mode, each of the (1-1)-th light emitting element LD1-1 and the (1-3)-th light emitting element LD1-3 may not emit light in the first display area DA1, and the (2-1)-th light emitting element LD2-1 may emit light in the first display area DA1.

The second light emitting element LD2 may emit the second right light PX2-LR traveling in the right direction and the second front light PX2-LF traveling in the front direction.

The third light blocking patterns LBP3 may absorb a portion of the light emitted from the second light emitting element LD2. In more detail, the third light blocking patterns LBP3 may absorb the second right light PX2-LR traveling at an angle greater than the third angle AGL3 in the right direction. In other words, when an angle between the imaginary straight line extending perpendicular or substantially perpendicular to the second light emitting element LD2 and the direction in which the second right light PX2-LR emitted from the second light emitting element LD2 travels is greater than the third angle AGL3, the second right light PX2-LR may be absorbed by the third light blocking patterns LBP3. Accordingly, the third light blocking patterns LBP3 may adjust a viewing angle in the right direction. For example, the third angle AGL3 may be about 45 degrees.

When the display device DD2 is driven in the second mode (e.g., the narrow viewing angle mode), a passenger positioned at (e.g., in or on) the right direction of the first display area DA1 may not view the second right light PX2-LR traveling at an angle greater than the third angle AGL3. Accordingly, the passenger may not view an image displayed in the first display area DA1. On the other hand, a driver positioned at (e.g., in or on) the front direction of the first display area DA1 may view the second front light PX2-LF. Accordingly, the driver may view the image displayed in the first display area DA1.

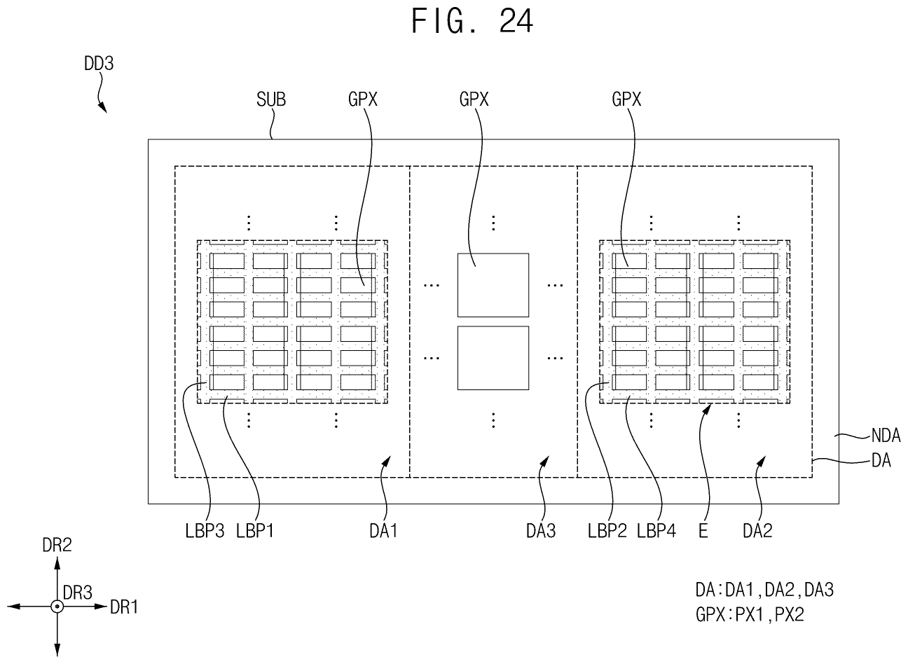

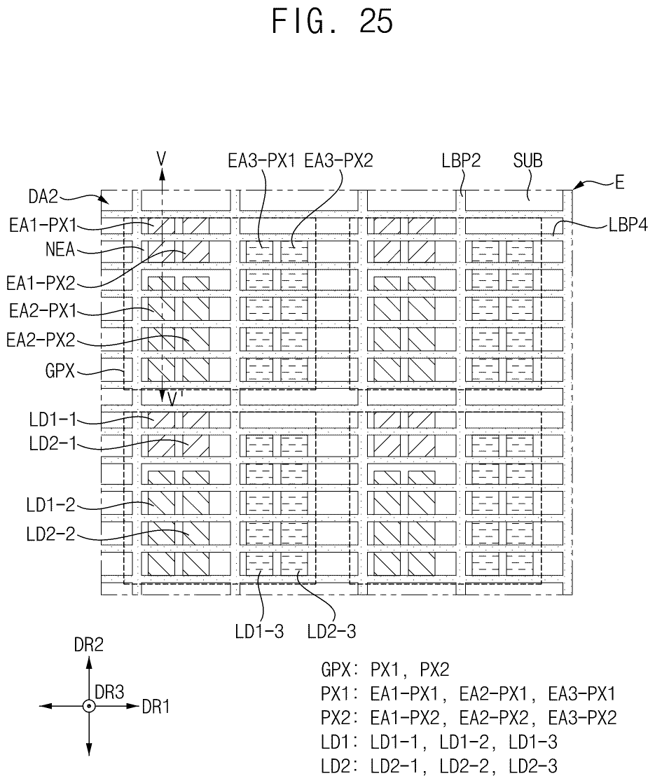

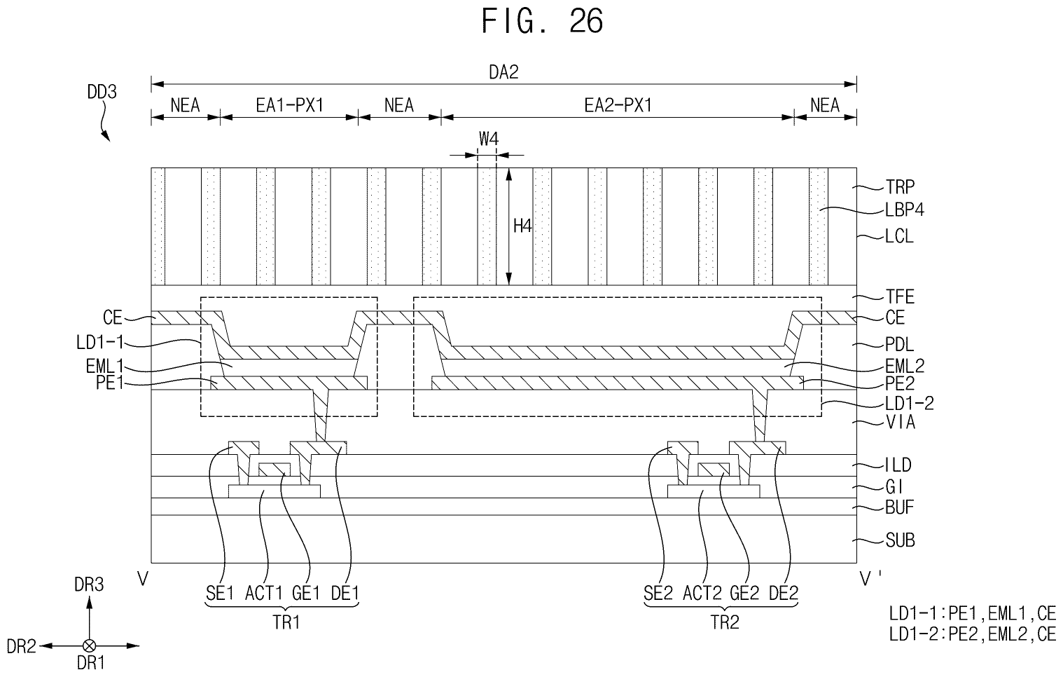

FIG. 24 is a plan view illustrating a display device according to another embodiment of the present disclosure. FIG. 25 is an enlarged plan view of the area ‘E’ of FIG. 24. FIG. 26 is a cross-sectional view taken along the line V-V′ of FIG. 25.

Referring to FIGS. 24 and 25, a display device DD3 according to another embodiment of the present disclosure may include the substrate SUB, the group pixels GPX, the first light blocking patterns LBP1, the second light blocking patterns LBP2, the third light blocking patterns LBP3, and fourth light blocking patterns LBP4.

The display device DD3 may be the same or substantially the same as the display device DD2 described above with reference to FIGS. 18 to 23, except that the display device DD3 may further include the fourth light blocking patterns LBP4 in the second display area DA2. Hereinafter, redundant description of the same or substantially the same components as those of the display device DD2 described above with reference to FIGS. 18 to 23 may not be repeated or may be simplified.

The group pixels GPX may be repeatedly disposed along the first direction DR1 and the second direction DR2 on the substrate SUB in the second display area DA2. Each of the group pixels GPX may include the first pixel PX1 and the second pixel PX2. For example, the first pixel PX1 may correspond to the left pixel of the group pixel GPX, and the second pixel PX2 may correspond to the right pixel of the group pixel GPX.

The fourth light blocking patterns LBP4 may be repeatedly disposed along the second direction DR2 on the substrate SUB in the second display area DA2. The fourth light blocking patterns LBP4 may be spaced apart from each other in the second direction DR2 in the second display area DA2. Each of the fourth light blocking patterns LBP4 may extend in the first direction DR1.

Referring further to FIG. 26, the display device DD3 according to another embodiment of the present disclosure may include the substrate SUB, the buffer layer BUF, the first thin film transistor TR1, the second thin film transistor TR2, the gate insulating layer GI, the inter-layer insulating layer ILD, the via-insulating layer VIA, the (1-1)-th light emitting element LD1-1, the (1-2)-th light emitting element LD1-2, the pixel defining layer PDL, the encapsulation layer TFE, and a light control layer LCL in the second display area DA2.

The light control layer LCL may be disposed on the encapsulation layer TFE. The light control layer LCL may include the fourth light blocking patterns LBP4 and the transmission patterns TRP. The transmission patterns TRP may surround (e.g., around peripheries of) the fourth light blocking patterns LBP4. Light emitted from the (1-1)-th light emitting element LD1-1 and the (1-2)-th light emitting element LD1-2 may pass through the transmission patterns TRP. The fourth light blocking patterns LBP4 may be repeatedly disposed along the second direction DR2, and may be spaced apart from each other by a suitable distance (e.g., a predetermined distance).

In an embodiment, the fourth light blocking patterns LBP4 may be disposed in the same layer as that of the first light blocking patterns LBP1, the second light blocking patterns LBP2, and the third light blocking patterns LBP3. In other words, the first light blocking patterns LBP1, the second light blocking patterns LBP2, the third light blocking patterns LBP3, and the fourth light blocking patterns LBP4 may include the same material as each other and may be formed through the same process. Accordingly, a process efficiency for manufacturing the display device DD3 may be improved.

In an embodiment, a fourth height H4 of the fourth light blocking pattern LBP4 may be equal to or substantially equal to the first height (e.g., the first height H1 of FIG. 3) of the first light blocking pattern LBP1, the second height (e.g., the second height H2 of FIG. 5) of the second light blocking pattern LBP2, and the second height (e.g., the second height H3 of FIG. 20) of the third light blocking pattern LBP3. For example, the fourth height H4 of the fourth light blocking pattern LBP4 may be about 40 micrometers to about 48 micrometers.

In an embodiment, as illustrated in FIG. 25, some of the fourth light blocking patterns LBP4 may partially overlap with the first light emitting element LD1 and the second light emitting element LD2 in a plan view. In other words, some of the fourth light blocking patterns LBP4 may partially overlap with the first light emitting element LD1 and the second light emitting element LD2 in a plan view, and other portions of the fourth light blocking patterns LBP4 may not overlap with the first light emitting element LD1 and the second light emitting element LD2 in a plan view. For example, as illustrated in FIG. 26, some of the fourth light blocking patterns LBP4 may partially overlap with the (1-1)-th light emitting element LD1-1 and the (1-2)-th light emitting element LD1-2 in a plan view. However, the present disclosure is not limited thereto, and all of the fourth light blocking patterns LBP4 may partially overlap with the first light emitting element LD1 and the second light emitting element LD2 in a plan view.

In an embodiment, each of the fourth light blocking patterns LBP4 may include an organic material including a light blocking material having a black color. Accordingly, the fourth light blocking patterns LBP4 may selectively block some of the light emitted from the first pixel PX1 and the second pixel PX2. For example, the fourth light blocking patterns LBP4 may selectively block some of the light emitted from the (1-1)-th light emitting element LD1-1 and the (1-2)-th light emitting element LD1-2. In other words, the fourth light blocking patterns LBP4 may adjust a viewing angle of the display device DD3 by selectively absorbing some of the light emitted from the (1-1)-th light emitting element LD1-1 and the (1-2)-th light emitting element LD1-2. In more detail, the fourth light blocking patterns LBP4 may adjust a viewing angle in the second direction DR2 (e.g., the up-down direction).

For example, a fourth width W4 of the fourth light blocking pattern LBP4 may be smaller than the second width (e.g., the second width W2 of FIG. 5) of the second light blocking pattern LBP2 and the third width (e.g., the third width W3 of FIG. 20) of the third light blocking pattern LBP3. Here, the fourth width W4 may refer to a length of the fourth light blocking pattern LBP4 in the second direction DR2. The second width may refer to a length of the second light blocking pattern LBP2 in the first direction DR1. The third width may refer to a length of the third light blocking pattern LBP3 in the first direction DR1. However, the present disclosure is not limited thereto.

In addition, the fourth width W4 of the fourth light blocking pattern LBP4 may be equal to or substantially equal to the first width (e.g., the first width W1 of FIG. 3) of the first light blocking pattern LBP1. Here, the first width may refer to a length of the first light blocking pattern LBP1 in the second direction DR2. However, the present disclosure is not limited thereto.

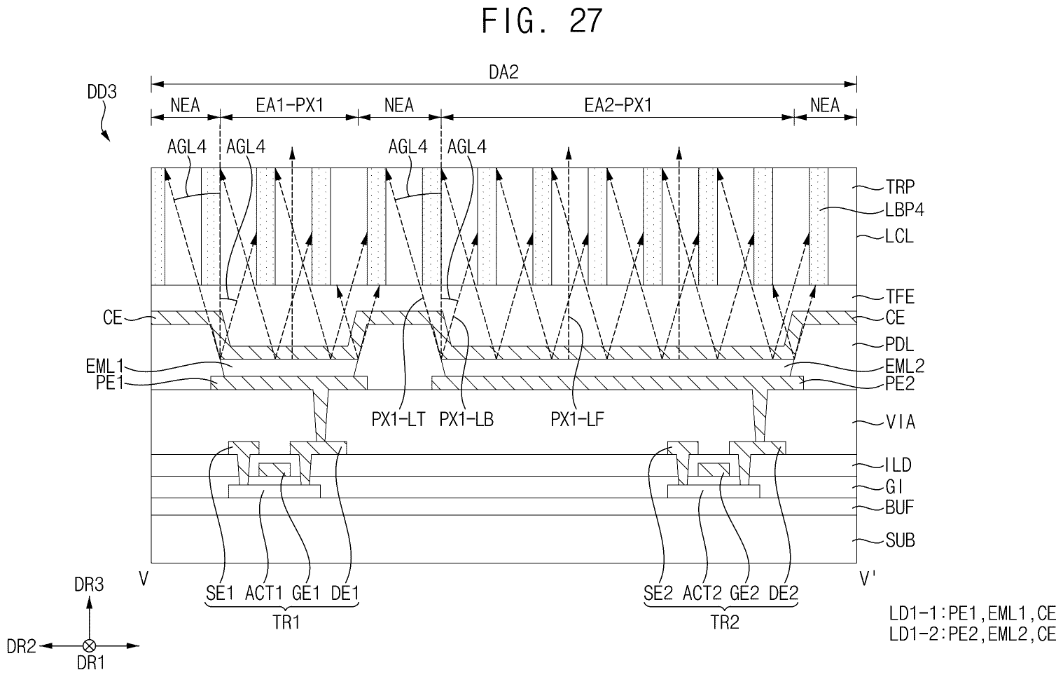

FIG. 27 is a cross-sectional view taken along the line V-V′ of FIG. 25. For example, FIG. 27 is a cross-sectional view illustrating an absorption of light by the fourth light blocking patterns LBP4.

Referring to FIGS. 25 and 27, the first light emitting element LD1 of the first pixel PX1 may emit light in the second display area DA2. For example, each of the (1-1)-th light emitting element LD1-1 and the (1-2)-th light emitting element LD1-2 may emit light in the second display area DA2. The second light emitting element LD2 of the second pixel PX2 may also emit light in the second display area DA2. Hereinafter, the first light emitting element LD1 may be described in more detail, and redundant description with respect to the second light emitting element LD2 may not be repeated.

For example, the second display area DA2 may be positioned at (e.g., in or on) the right side of the display area (e.g., the display area DA of FIG. 24). When the display device DD3 is applied to an automotive display device, a passenger seat may be positioned at (e.g., in or on) the front direction of the second display area DA2.

The first light emitting element LD1 may emit first upper light PX1-LT traveling in the upward direction, first front light PX1-LF traveling in the front direction, and first lower light PX1-LB traveling in the downward direction. For example, each of the (1-1)-th light emitting element LD1-1 and the (1-2)-th light emitting element LD1-2 may emit the first upper light PX1-LT, the first front light PX1-LF, and the first lower light PX1-LB.

Similarly, the second light emitting element LD2 may emit second upper light traveling in the upward direction, second front light traveling in the front direction, and second lower light traveling in the downward direction.

The fourth light blocking patterns LBP4 may absorb some of the light emitted from the first light emitting element LD1 and the second light emitting element LD2. In more detail, the fourth light blocking patterns LBP4 may absorb the first upper light PX1-LT traveling at an angle greater than a fourth angle AGL4 in the upward direction. In other words, when an angle between an imaginary straight line extending perpendicular or substantially perpendicular to the first light emitting element LD1 and a direction in which the first upper light PX1-LT emitted from the first light emitting element LD1 travels is greater than the fourth angle AGL4, the first upper light PX1-LT may be absorbed by the fourth light blocking patterns LBP4. Accordingly, the fourth light blocking patterns LBP4 may adjust a viewing angle in the upward direction. In an embodiment, the fourth angle AGL4 may be equal to or substantially equal to the second angle (e.g., the second angle AGL2 of FIG. 17). However, the present disclosure is not limited thereto. For example, the fourth angle AGL4 may be about 30 degrees.

In addition, the fourth light blocking patterns LBP4 may absorb the first lower light PX1-LB traveling at an angle greater than the fourth angle AGL4 in the downward direction. In other words, when an angle between the imaginary straight line extending perpendicular or substantially perpendicular to the first light emitting element LD1 and a direction in which the first lower light PX1-LB emitted from the first light emitting element LD1 travels is greater than the fourth angle AGL4, the first lower light PX1-LB may be absorbed by the fourth light blocking patterns LBP4. Accordingly, the fourth light blocking patterns LBP4 may adjust a viewing angle in the downward direction.

In other words, the fourth light blocking patterns LBP4 may adjust a viewing angle in the up-down direction. In more detail, the fourth light blocking patterns LBP4 may adjust the viewing angle in the up-down direction when the display device DD3 is driven in the second mode (e.g., the narrow viewing angle mode), and the fourth light blocking patterns LBP4 may adjust the viewing angle in the up-down direction when the display device DD3 is driven in the first mode (e.g., the wide viewing angle mode). As a result, a problem that an image displayed in the second display area DA2 is reflected on a front windshield of the automobile, which may interfere with the driver's operation, may be suppressed.

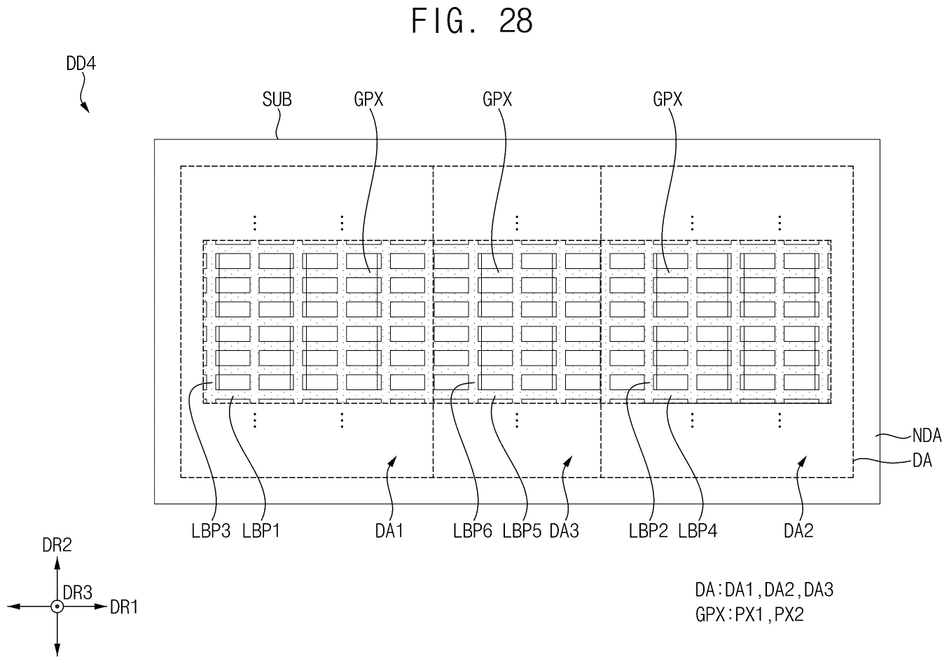

FIG. 28 is a plan view illustrating a display device according to another embodiment of the present disclosure.

Referring to FIG. 28, a display device DD4 according to another embodiment of the present disclosure may include the substrate SUB, the group pixels GPX, the first light blocking patterns LBP1, the second light blocking patterns LBP2, the third light blocking patterns LBP3, the fourth light blocking patterns LBP4, fifth light blocking patterns LBP5, and sixth light blocking patterns LBP6.

The display device DD4 may be the same or substantially the same as the display device DD3 described above with reference to FIGS. 22 to 25, except that the display device DD4 may further include the fifth blocking patterns LBP5 and the sixth blocking patterns LBP6 in the third display area DA3. Hereinafter, redundant description of the same or substantially the same components as those of the display device DD3 described above with reference to FIGS. 22 to 25 may not be repeated or may be simplified.

The group pixels GPX may be repeatedly disposed along the first direction DR1 and the second direction DR2 on the substrate SUB in the third display area DA3. Each of the group pixels GPX may include the first pixel PX1 and the second pixel PX2. For example, the first pixel PX1 may correspond to the left pixel of the group pixel GPX, and the second pixel PX2 may correspond to the right pixel of the group pixel GPX.

The fifth light blocking patterns LBP5 may be repeatedly disposed along the second direction DR2 on the substrate SUB in the third display area DA3. The fifth light blocking patterns LBP5 may be spaced apart from each other in the second direction DR2 in the third display area DA3. Each of the fifth light blocking patterns LBP5 may extend in the first direction DR1. In an embodiment, the fifth light blocking pattern LBP5 may be connected to the first light blocking pattern LBP1 and the fourth light blocking 1 pattern LBP4. In other words, the first light blocking pattern LBP1, the fourth light blocking pattern LBP4, and the fifth light blocking pattern LBP5 may be connected to each other and extend continuously.

In an embodiment, each of the fifth light blocking patterns LBP5 may include an organic material including a light blocking material having a black color. The fifth light blocking patterns LBP5 may adjust a viewing angle in the second direction DR2 (e.g., the up-down direction). For example, the fifth light blocking patterns LBP5 may adjust the viewing angle in the up-down direction similar to that of the first light blocking patterns LBP1 illustrated in FIG. 17 and the fourth light blocking patterns LBP4 illustrated in FIG. 27. As a result, a problem that an image displayed in the third display area DA3 is reflected on a front windshield of the automobile, which may interfere with the driver's operation, may be suppressed.

The sixth light blocking patterns LBP6 may be repeatedly disposed along the first direction DR1 on the substrate SUB in the third display area DA3. The sixth light blocking patterns LBP6 may be spaced apart from each other in the first direction DR1 in the third display area DA3. Each of the sixth light blocking patterns LBP6 may extend in the second direction DR2.

In an embodiment, each of the sixth light blocking patterns LBP6 may include an organic material including a light blocking material having a black color. The sixth light blocking patterns LBP6 may adjust a viewing angle in the first direction DR1 (e.g., the left-right direction). For example, the sixth light blocking patterns LBP6 may adjust a viewing angle in the left direction similar to that of the second light blocking patterns LBP2 illustrated in FIG. 11. In this case, the driver may not view the image displayed in the third display area DA3. On the other hand, the passenger may view the image displayed in the third display area DA3.

As another example, the sixth light blocking patterns LBP6 may adjust a viewing angle in the right direction similar to that of the third light blocking patterns LBP3 illustrated in FIG. 23. In this case, the driver may view the image displayed in the third display area DA3. On the other hand, the passenger may not view the image displayed in the third display area DA3.

In an embodiment, the first light blocking patterns LBP1, the second light blocking patterns LBP2, the third light blocking patterns LBP3, the fourth light blocking patterns LBP4, the fifth light blocking patterns LBP5, and the sixth light blocking patterns LBP6 may be disposed in the same layer as each other. In other words, the first light blocking patterns LBP1, the second light blocking patterns LBP2, the third light blocking patterns LBP3, the fourth light blocking patterns LBP4, the fifth light blocking patterns LBP5, and the sixth light blocking patterns LBP6 may be formed through the same process. Accordingly, a process efficiency for manufacturing the display device DD4 may be improved.

In an embodiment, the first light blocking patterns LBP1, the second light blocking patterns LBP2, the third light blocking patterns LBP3, the fourth light blocking patterns LBP4, the fifth light blocking patterns LBP5, and the sixth light blocking patterns LBP6 may have the same or substantially the same height as each other.

Embodiments of present disclosure described above may be applied to various suitable display devices. For example, one or more embodiments of the present disclosure described above may be applicable to various suitable display devices, such as display devices for vehicles, ships, aircrafts, portable communication devices, and the like, display devices for exhibition or information transmission, medical display devices, and the like.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising a display area including a first display area, and a second display area spaced from the first display area in a first direction;
a plurality of pixels located along the first direction and a second direction crossing the first direction on the substrate in the display area;
a plurality of first light blocking patterns located along the second direction on the substrate in the first display area, each of the plurality of first light blocking patterns extending in the first direction; and
a plurality of second light blocking patterns located along the first direction on the substrate in the second display area, each of the plurality of second light blocking patterns extending in the second direction,
wherein the plurality of second light blocking patterns and the plurality of first light blocking patterns have the same height as each other.

2. The display device of claim 1, wherein the plurality of first light blocking patterns and the plurality of second light blocking patterns are located in the same layer as each other.

3. The display device of claim 1, wherein each of the plurality of pixels comprises:
a first pixel including a first light emitting element; and
a second pixel including a second light emitting element configured to emit light of the same color as that of the first light emitting element, and
wherein a first pixel electrode of the first light emitting element is spaced from a second pixel electrode of the second light emitting element.

4. The display device of claim 3, wherein in the first display area, some of the plurality of first light blocking patterns partially overlap with the first light emitting element and the second light emitting element in a plan view.

5. The display device of claim 3, wherein in the second display area, the plurality of second light blocking patterns are spaced from the first light emitting element and the second light emitting element in a plan view.

6. The display device of claim 3, wherein:
when the display device is driven in a first mode, each of the first light emitting element and the second light emitting element is configured to emit light in the second display area; and
when the display device is driven in a second mode different from the first mode, the first light emitting element is configured to emit light and the second light emitting element is configured to not emit light in the second display area.

7. The display device of claim 3, wherein:
when the display device is driven in a first mode, the first light emitting element is configured to not emit light and the second light emitting element is configured to emit light in the second display area; and
when the display device is driven in a second mode different from the first mode, the first light emitting element is configured to emit light and the second light emitting element is configured to not emit light in the second display area.

8. The display device of claim 1, wherein each of the plurality of first light blocking patterns and the plurality of second light blocking patterns comprises an organic material including a light blocking material having a black color.

9. The display device of claim 1, wherein the display area further includes a third display area between the first display area and the second display area, some of the plurality of pixels being located in the third display area, and
wherein the plurality of first light blocking patterns and the plurality of second light blocking patterns are spaced from the third display area in a plan view.

10. A display device comprising:
a substrate comprising a display area including a first display area, and a second display area spaced from the first display area in a first direction;
a plurality of pixels located along the first direction and a second direction crossing the first direction on the substrate in the display area;
a plurality of first light blocking patterns located along the second direction on the substrate in the first display area, each of the plurality of first light blocking patterns extending in the first direction;
a plurality of second light blocking patterns located along the first direction on the substrate in the second display area, each of the plurality of second light blocking patterns extending in the second direction; and
a plurality of third light blocking patterns located along the first direction on the substrate in the first display area, each of the plurality of third light blocking patterns extending in the second direction,
wherein the plurality of first light blocking patterns, the plurality of second light blocking patterns, and the plurality of third light blocking patterns have the same height as each other.

11. The display device of claim 10, wherein the plurality of first light blocking patterns, the plurality of second light blocking patterns, and the plurality of third light blocking patterns are located in the same layer as each other.

12. The display device of claim 10, wherein each of the plurality of pixels comprises:
a first pixel including a first light emitting element; and
a second pixel including a second light emitting element configured to emit light of the same color as that of the first light emitting element, and
wherein a first pixel electrode of the first light emitting element is spaced from a second pixel electrode of the second light emitting element.

13. The display device of claim 12, wherein in the first display area, some of the plurality of first light blocking patterns partially overlap with the first light emitting element and the second light emitting element in a plan view.

14. The display device of claim 12, wherein the plurality of second light blocking patterns are spaced from the first light emitting element and the second light emitting element in a plan view in the second display area, and
wherein the plurality of third light blocking patterns are spaced from the first light emitting element and the second light emitting element in a plan view in the first display area.

15. The display device of claim 12, wherein:
when the display device is driven in a first mode, each of the first light emitting element and the second light emitting element is configured to emit light in the first display area and the second display area;
when the display device is driven in a second mode different from the first mode, the first light emitting element is configured to not emit light and the second light emitting element is configured to emit light in the first display area; and
when the display device is driven in the second mode, the first light emitting element is configured to emit light and the second light emitting element is configured to not emit light in the second display area.

16. The display device of claim 12, wherein:
when the display device is driven in a first mode, the first light emitting element is configured to emit light and the second light emitting element is configured to not emit light in the first display area;
when the display device is driven in the first mode, the first light emitting element is configured to not emit light and the second light emitting element is configured to emit light in the second display area;
when the display device is driven in a second mode different from the first mode, the first light emitting element is configured to not emit light and the second light emitting element is configured to emit light in the first display area; and
when the display device is driven in the second mode, the first light emitting element is configured to emit light and the second light emitting element is configured to not emit light in the second display area.

17. The display device of claim 10, wherein each of the plurality of first light blocking patterns, the plurality of second light blocking patterns, and the plurality of third light blocking patterns comprises an organic material including a light blocking material having a black color.

18. The display device of claim 10, wherein the display area further comprises a third display area between the first display area and the second display area, some of the plurality of pixels being located in the third display area, and
wherein the plurality of first light blocking patterns, the plurality of second light blocking patterns, and the plurality of third light blocking patterns are spaced from the third display area in a plan view.

19. A display device comprising:
a substrate comprising a display area including a first display area, and a second display area spaced from the first display area in a first direction;
a plurality of pixels located along the first direction and a second direction crossing the first direction on the substrate in the display area;
a plurality of first light blocking patterns located along the second direction on the substrate in the first display area, each of the plurality of first light blocking patterns extending in the first direction;
a plurality of second light blocking patterns located along the first direction on the substrate in the second display area, each of the plurality of second light blocking patterns extending in the second direction;
a plurality of third light blocking patterns located along the first direction on the substrate in the first display area, each of the plurality of third light blocking patterns extending in the second direction; and
a plurality of fourth light blocking patterns located along the second direction on the substrate in the second display area, each of the plurality of fourth light blocking patterns extending in the first direction,
wherein the plurality of first light blocking patterns, the plurality of second light blocking patterns, the plurality of third light blocking patterns, and the plurality of fourth light blocking patterns have the same height as each other.

20. The display device of claim 19, wherein the plurality of first light blocking patterns, the plurality of second light blocking patterns, the plurality of third light blocking patterns, and the plurality of fourth light blocking patterns are located in the same layer as each other.

21. The display device of claim 19, wherein each of the plurality of pixels comprises:
a first pixel including a first light emitting element; and
a second pixel including a second light emitting element configured to emit light of the same color as that of the first light emitting element, and
wherein a first pixel electrode of the first light emitting element is spaced from a second pixel electrode of the second light emitting element.

22. The display device of claim 21, wherein some of the plurality of first light blocking patterns partially overlap with the first light emitting element and the second light emitting element in the first display area in a plan view, and
wherein some of the plurality of fourth light blocking patterns partially overlap with the first light emitting element and the second light emitting element in the second display area in a plan view.

23. The display device of claim 21, wherein the plurality of second light blocking patterns are spaced from the first light emitting element and the second light emitting element in the second display area in a plan view, and
wherein the plurality of third light blocking patterns are spaced from the first light emitting element and the second light emitting element in the first display area in a plan view.

24. The display device of claim 21, wherein:
when the display device is driven in a first mode, each of the first light emitting element and the second light emitting element is configured to emit light in the first display area and the second display area;
when the display device is driven in a second mode different from the first mode, the first light emitting element is configured to not emit light and the second light emitting element is configured to emit light in the first display area; and
when the display device is driven in the second mode, the first light emitting element is configured to emit light and the second light emitting element is configured to not emit light in the second display area.

25. The display device of claim 21, wherein:
when the display device is driven in a first mode, the first light emitting element is configured to emit light and the second light emitting element is configured to not emit light in the first display area;
when the display device is driven in the first mode, the first light emitting element is configured to not emit light and the second light emitting element is configured to emit light in the second display area;
when the display device is driven in a second mode different from the first mode, the first light emitting element is configured to not emit light and the second light emitting element is configured to emit light in the first display area; and
when the display device is driven in the second mode, the first light emitting element is configured to emit light and the second light emitting element is configured to not emit light in the second display area.

26. The display device of claim 19, wherein each of the plurality of first light blocking patterns, the plurality of second light blocking patterns, the plurality of third light blocking patterns, and the plurality of fourth light blocking patterns comprises an organic material including a light blocking material having a black color.

27. The display device of claim 19, wherein the display area further comprises a third display area between the first display area and the second display area, some of the plurality of pixels being located in the third display area.

28. The display device of claim 27, wherein the plurality of first light blocking patterns, the plurality of second light blocking patterns, the plurality of third light blocking patterns, and the plurality of fourth light blocking patterns are spaced from the third display area in a plan view.

29. The display device of claim 27, further comprising:
a plurality of fifth light blocking patterns located along the second direction on the substrate in the third display area, each of the plurality of fifth light blocking patterns extending in the first direction; and
a plurality of sixth light blocking patterns located along the first direction on the substrate in the third display area, each of the plurality of sixth light blocking patterns extending in the second direction,
wherein the plurality of first light blocking patterns, the plurality of second light blocking patterns, the plurality of third light blocking patterns, the plurality of fourth light blocking patterns, the plurality of fifth light blocking patterns, and the plurality of sixth light blocking patterns have the same height as each other.

30. The display device of claim 29, wherein the plurality of first light blocking patterns, the plurality of second light blocking patterns, the plurality of third light blocking patterns, the plurality of fourth light blocking patterns, the plurality of fifth light blocking patterns, and the plurality of sixth light blocking patterns are located in the same layer as each other.

31. The display device of claim 29, wherein the plurality of fifth light blocking patterns are connected to the plurality of first light blocking patterns and the plurality of fourth light blocking patterns.
